(19) United States
(12) Patent Application Publication
(10) Pub. No.: US 2018/0040365 A1
(43) Pub. Date: Feb. 8, 2018

(54) SEMICONDUCTOR DEVICE AND METHOD FOR MANUFACTURING THE SAME

(71) Applicant: Renesas Electronics Corporation, Tokyo (JP)

(72) Inventors: Yukio MAKI, Tokyo (JP); Yoshiyuki ISHIGAKI, Tokyo (JP); Toshiaki TAI, Tokyo (JP); Hideaki YAMAKOSHI, Tokyo (JP); Toshihiko HIROSE, Tokyo (JP); Takuya ISHIDA, Tokyo (JP)

(73) Assignee: Renesas Electronics Corporation, Tokyo (JP)

(21) Appl. No.: 15/631,101

(22) Filed: Jun. 23, 2017

(30) Foreign Application Priority Data
Aug. 3, 2016 (JP) 2016-152859

(51) Int. Cl. G11C 11/417; H01L 23/535; H01L 21/265; H01L 27/11

(52) U.S. Cl. CPC G11C 11/417; H01L 27/1104; H01L 23/535; H01L 21/265

(57) ABSTRACT

A semiconductor device which suppresses soft errors and functions as a non-volatile memory and a method for manufacturing the same. In the semiconductor device, a first non-volatile memory element and a second non-volatile memory element are electrically coupled to a first memory node and a second memory node through a first MOS transistor and a second MOS transistor respectively. A first capacitor and a second capacitor each have a storage node electrically coupled to the first memory node and the second memory node respectively and each have a cell plate to form a capacitance between the storage node and the cell plate.

### CROSS-REFERENCE TO RELATED APPLICATIONS

The disclosure of Japanese Patent Application No. 2016-152859 filed on Aug. 3, 2016 including the specification, drawings and abstract is incorporated herein by reference in its entirety.

### BACKGROUND

The present invention relates to a semiconductor device and a method for manufacturing the same.

Among high speed accessible non-volatile memories are nvSRAMs (non-volatile Static Random Access Memories). For example, an nvSRAM is described in M. Fliesler et al., “A 15 ns 4 Mb NVSRAM in 0.13 u SONOS Technology”, 2008 IEEE, pp. 83-86 (Non-patent Literature 1).

An nvSRAM includes an SPAM which has six ordinary transistors, MONOS (Metal-Oxide-Nitride-Oxide-Silicon) transistors which store data when the power is off, and transistors which couple the MONOS transistors to the SRAM. Therefore, one cell of the nvSRAM includes twelve transistors.

In an nvSRAM, during normal operation when the SRAM operates, high speed random access is possible. When the power is off, the data in the SRAM is written in the MONOS transistor and when the power is turned back on, the data in the MONOS transistor is restored in the SRAM. Thus the nvSRAM functions as a non-volatile memory.

On the other hand, for example, Japanese Unexamined Patent Application Publication No. 2004-79696 (Patent Literature 1) describes a structure in which a capacitor is added to the storage node of an SRAM having a full CMOS (Complementary Oxide Semiconductor) transistor.

### SUMMARY

In the nvSRAM, as the SRAM memory cell size is smaller, the capacitance component stored by the memory cell decreases. As a result, the electric charge amount required to invert the held data (critical charge amount) decreases and a slight noise inverts the held data. For this reason, as alpha rays and neutron rays enter the semiconductor substrate and collide against the atomic nucleus of elements and the generated charged ions induce a large amount of charge. This often inverts the held data and causes a soft error.

The above and further objects and novel features of the invention will more fully appear from the following detailed description in this specification and the accompanying drawings.

According to one aspect of the present invention, a first non-volatile memory element is electrically coupled to a first memory node through a first write switch element. A first capacitor has a first storage node electrically coupled to the first memory node and a first cell plate which forms a capacitance between the first storage node and the cell plate.

According to the present invention, there are provided a semiconductor device which suppresses soft errors and functions as a non-volatile memory and a method for manufacturing the same.

### BRIEF DESCRIPTION OF THE DRAWINGS

FIG. 1 is a plan view which schematically shows the configuration of a semiconductor device in the form of a chip according to a first embodiment of the invention;

FIG. 2 is a circuit diagram of a memory cell formed in the memory cell array of the semiconductor device shown in FIG. 1;

FIG. 3 is a sectional view which shows part of the memory cell array of the semiconductor device shown in FIG. 1;

FIG. 4 is a circuit diagram of a memory cell as a comparative example;

FIG. 5 is a circuit diagram of a memory cell of a semiconductor device according to a second embodiment of the invention;

FIG. 6 is a plan view which shows the configuration of a non-volatile memory region of the memory cell shown in FIG. 5;

FIG. 7 is a schematic sectional view taken along the line VII-VII of FIG. 6;

FIG. 8 is a plan view which shows the first layer of the planar layout of FIG. 6;

FIG. 9 is a plan view which shows the second layer of the planar layout of FIG. 6;

FIG. 10 is a plan view which shows the third layer of the planar layout of FIG. 6;

FIG. 11 is a graph which shows the write characteristics of a MONOS transistor;

FIG. 12 is a graph which shows the Vg-Id characteristics of a MONOS transistor;

FIG. 13 is a schematic sectional view which shows the first step of the method for manufacturing the semiconductor device according to the second embodiment;

FIG. 14 is a schematic sectional view which shows the second step of the method for manufacturing the semiconductor device according to the second embodiment;

FIG. 15 is a schematic sectional view which shows the third step of the method for manufacturing the semiconductor device according to the second embodiment;

FIG. 16 is a schematic sectional view which shows the fourth step of the method for manufacturing the semiconductor device according to the second embodiment;

FIG. 17 is a schematic sectional view which shows the fifth step of the method for manufacturing the semiconductor device according to the second embodiment;

FIG. 18 is a schematic sectional view which shows the sixth step or the method for manufacturing the semiconductor device according to the second embodiment;

FIG. 19 is a schematic sectional view which shows the seventh step of the method for manufacturing the semiconductor device according to the second embodiment;

FIG. 20 is a schematic sectional view which shows the eighth step of the method for manufacturing the semiconductor device according to the second embodiment;

FIG. 21 is a schematic sectional view which shows the ninth step of the method for manufacturing the semiconductor device according to the second embodiment;

FIG. 22 is a schematic sectional view which shows the tenth step of the method for manufacturing the semiconductor device according to the second embodiment;

FIG. 23 is a schematic sectional view which shows the eleventh step of the method for manufacturing the semiconductor device according to the second embodiment;

FIG. 24 is a schematic sectional view which shows the twelfth step of the method for manufacturing the semiconductor device according to the second embodiment;

FIG. 25 is a schematic sectional view which shows the thirteenth step of the method for manufacturing the semiconductor device according to the second embodiment;

FIG. 26 is a schematic sectional view which shows the fourteenth step of the method for manufacturing the semiconductor device according to the second embodiment;

FIG. 27 is a schematic sectional view which shows the fifteenth step of the method for manufacturing the semiconductor device according to the second embodiment;

FIG. 28 is a plan view which shows the configuration of a non-volatile memory region of a memory cell of a semiconductor device according to a third embodiment of the invention;

FIG. 29 is a schematic sectional view taken along the line XXIX-XXIX of FIG. 28;

FIG. 30 is a plan view which shows the first layer of the planar layout of FIG. 28;

FIG. 31 is a plan view which shows the second layer of the planar layout of FIG. 28;

FIG. 32 is a plan view which shows the third layer of the planar layout of FIG. 28;

FIG. 33 is a schematic sectional view which shows the first step of the method for manufacturing the semiconductor device according to the third embodiment;

FIG. 34 is a schematic sectional view which shows the second step of the method for manufacturing the semiconductor device according to the third embodiment;

FIG. 35 is a schematic sectional view which shows the third step of the method for manufacturing the semiconductor device according to the third embodiment;

FIG. 36 is a schematic sectional view which shows the fourth step of the method for manufacturing the semiconductor device according to the third embodiment;

FIG. 37 is a schematic sectional view which shows the fifth step of the method for manufacturing the semiconductor device according, to the third embodiment;

FIG. 38 is a schematic sectional view which shows the sixth step of the method for manufacturing the semiconductor device according to the third embodiment;

FIG. 39 is a schematic sectional view which shows the seventh step of the method for manufacturing the semiconductor device according to the third embodiment;

FIG. 40 is a schematic sectional view which shows the eighth step of the method for manufacturing the semiconductor device according to the third embodiment;

FIG. 41 is a schematic sectional view which shows the ninth step of the method for manufacturing the semiconductor device according to the third embodiment; and

FIG. 42 is a circuit diagram of a memory cell in which non-volatile memory elements other than MONOS elements are used.

### DETAILED DESCRIPTION

Next, the preferred embodiments of the present invention will be described referring to the accompanying drawings.

### First Embodiment

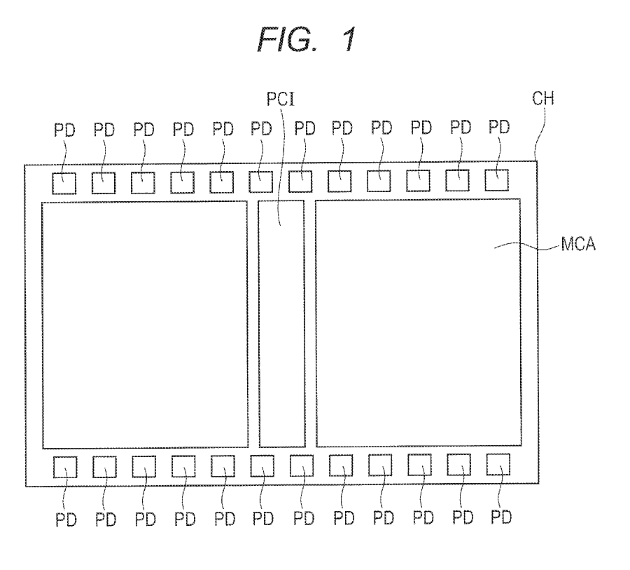

As shown in FIG. 1, a semiconductor device CH according to the first embodiment is in the form of a chip and has a semiconductor substrate. Memory cell arrays MCA, a peripheral circuit PCI, and pads PD are disposed on the surface of the semiconductor substrate.

For example, the two memory cell arrays MCA are arranged in a manner to sandwich the peripheral circuit PCI. The pads PD are arranged along the outer edges of the semiconductor device CH.

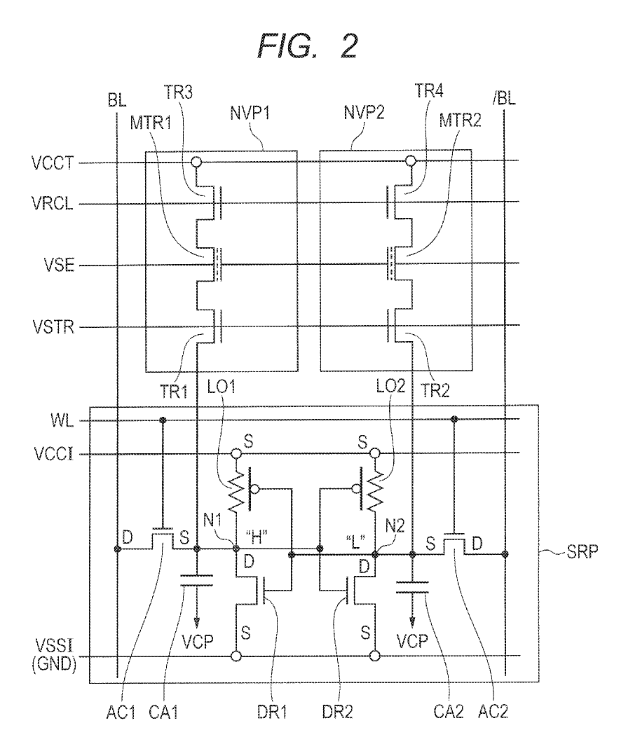

As shown in FIG. 2, a memory cell includes an SRAM part SRP and two non-volatile memory parts NVP1 and NVP2. For example, the SRAM part SRP includes a bit line pair BL and/BL, a word line WL, a flip flop circuit, a pair of access transistors AC1 and AC2, and a pair of capacitors CA1 and CA2.

The flip flop circuit has two CMOS inverters. One CMOS inverter (first inverter) includes a driver transistor (first driver transistor) DR1 and a load transistor (first load transistor) LO1. The other CMOS inverter (second inverter) includes a driver transistor (second driver transistor) DR2 and a load transistor (second load transistor) LO2.

The SRAM is a semiconductor storage device which eliminates the need for the so-called “refresh” process to restore the charge stored as information in a given cycle because it has a flip flop circuit. The SRAM according to the first embodiment further includes capacitors CA1 and CA2 which are equivalent to ones in a DRAM.

In the flip flop circuit, the gate electrodes of the driver transistor DR2 and load transistor LO2 and one electrode (storage node) of the capacitor (first capacitor) CA1 are electrically coupled to one (source S) of the paired source/drain of the access transistor (first access transistor) AC1. The one (source S) of the paired source/drain of the access transistor AC1 is electrically coupled to the drains D of the driver transistor DR1 and load transistor LO1. The region where the one (source S) of the paired source/drain of the access transistor AC1 is coupled to the drains D of the driver transistor DR1 and load transistor LO1 functions as a first memory node N1.

The gate electrodes of the driver transistor DR1 and load transistor LO1 and one electrode (storage node) of the capacitor (second capacitor) CA2 are electrically coupled to one (source S) of the paired source/drain of the access transistor (second access transistor) AC2, The one (source S) of the paired source/drain of the access transistor AC2 is electrically coupled to the drains D of the driver transistor DR2 and load transistor LO2. The region where the one (source S) of the paired source/drain of the access transistor AC2 is coupled to the drains D of the driver transistor DR2 and load transistor LO2 functions as a second memory node N2.

The sources S of the driver transistors DR1 and DR2 are electrically coupled to wiring VSSI with GND potential. The sources S of the load transistors LO1 and LO2 are electrically coupled to Vcc wiring (power supply wiring) VCCI which applies voltage Vcc. The other electrodes (cell plates) of the capacitors CA1 and CA2 are electrically coupled to wiring VCP which applies voltage Vcc/2 as one half of the voltage Vcc.

The bit line (first bit line) BL is electrically coupled to the other (drain D) of the paired Source/drain of the access transistor AC1. The bit line (second bit line)/BL is electrically coupled to the other (drain D) of the paired source/drain of the access transistor AC2. The word line WL is electrically coupled to the gate electrodes of the paired access transistors AC1 and AC2.

The driver transistors DR1 and DR2 which constitute the flip flop circuit are, for example, n-channel MOS transistors. The load transistors LO1 and LO2 are, for example, p-channel TFTs (Thin Film Transistors). The access transistors AC1 and AC2 are, for example, n-channel MOS transistors. Thus, the SRAM part SRP in this embodiment is an SRAM which has the load transistors LO1 and LO2 as TFTs and further includes the capacitors CA1 and CA2 equivalent to cries in a DRAM.

The non-volatile memory part (first non-volatile memory part) NVP1 includes a MONO transistor (first non-volatile memory element) MTR1, a MOS transistor (first write switch element) TR1, and a MOS transistor (first reset switch element) TR3.

One of the paired source/drain of the MONOS transistor MTR1 is electrically coupled to one of the paired source/drain of the MOS transistor TR1. The other of the paired source/drain of the MONOS transistor MTR1 is electrically coupled to one of the paired source/drain of the MOS transistor TR3.

The other of the paired source/drain of the MOS transistor TR1 is electrically coupled to the first memory node N1. The other of the paired source/drain of the MOS transistor TR3 is electrically coupled to wiring VCCT.

The non-volatile memory part (second non-volatile memory part) NVP2 includes a MONOS transistor (second non-volatile memory element) MTR2, a MOS transistor (second write switch element) TR2, and a MOS transistor (second reset switch element) TR4.

One of the paired source/drain of the MONOS transistor MTR2 is electrically coupled to one of the paired source/drain of the MOS transistor TR2. The other of the paired source/drain of the MONOS transistor MTR2 is electrically coupled to one of the paired source/drain of the MOS transistor TR4.

The other of the paired source/drain of the MOS transistor TR2 is electrically coupled to the second memory node N2. The other of the paired source/drain of the MOS transistor TR4 is electrically coupled to the wiring VCCT.

Both the gate electrode of the MONOS transistor MTR1 and the gate electrode of the MONOS transistor MTR2 are electrically coupled to wiring VSE. Both the gate electrode of the MOS transistor TR1 and the gate electrode of the MOS transistor TR2 are electrically coupled to wiring VSTR. Both the gate electrode of the MOS transistor TR3 and the gate electrode of the MOS transistor TR4 are electrically coupled to wiring VRCL.

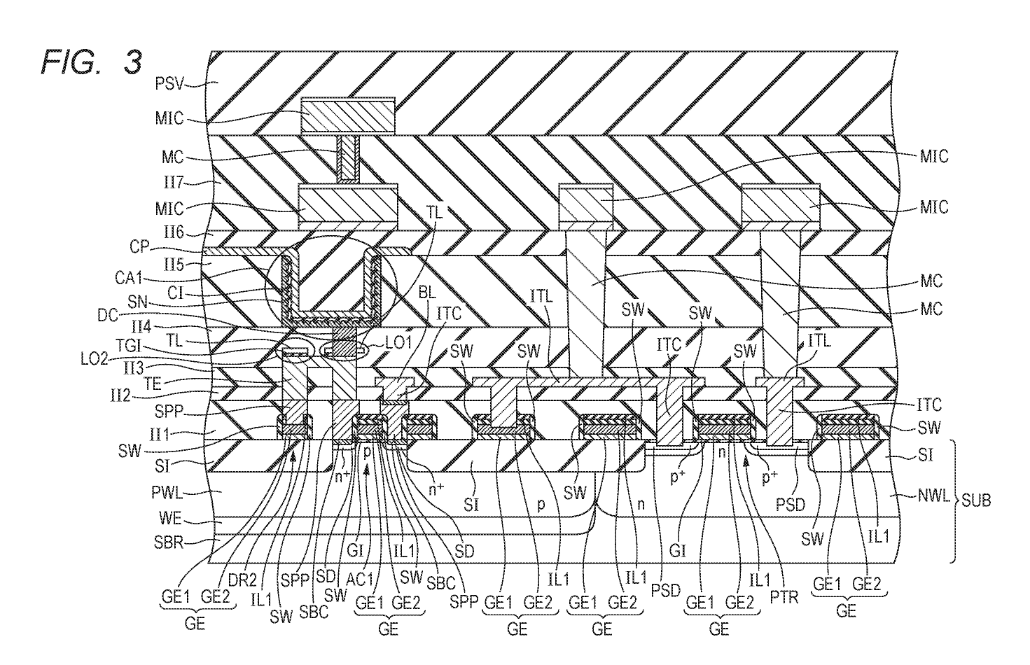

Next, the concrete structure of the semiconductor device which corresponds to the SRAM memory cell shown in FIG. 2 will be described referring to FIG. 3. The sectional view of FIG. 3 is not a figure which shows the cross section of a specific region but a figure which is intended to illustrate how the transistors and capacitors shown in FIG. 2 look like in the semiconductor device.

In FIG. 3, the region where the SRAM memory cell is formed is shown on the left and the region where the peripheral circuit is formed is shown on the right. The semiconductor device according to the first embodiment is formed, for example, on the main surface of a p-type semiconductor substrate SUB of monocrystalline silicon.

The main surface of the semiconductor substrate SUB is electrically isolated by STI (Shallow Trench Isolation). The STI is made by burying insulating film SI in a trench made in the main surface of the semiconductor substrate SUB. The transistors AC1, AC2, DR1, and DR2 for the SRAM memory cell and the MOS transistor PTR for the peripheral circuit are formed on the main surface of the semiconductor substrate SUB which is electrically isolated by STI. FIG. 3 shows the access transistor AC1 as a transistor for the SRAM memory cell.

A p-type region PWL is formed in the main surface of the semiconductor substrate SUB in the memory cell formation region shown on the left in the figure. A p-type region PWL and an n-type region NWL are formed in the main surface of the semiconductor substrate SUB in the peripheral circuit region shown on the right in the figure. The p-type region PWL and n-type region NWL are layers to adjust threshold voltage Vth. The p-type region PWL in the memory cell formation region and the p-type region PWL in the peripheral circuit region may constitute a single p-type region. The p-type region PWL is formed over a p-type well region WE.

Each of the transistors AC1, AC2, DR1, and DR2 for the SRAM memory cell includes a pair of source/drain regions SD, a gate insulating film GI, and a gate electrode GE.

The paired source/drain regions SD are spaced from each other in the main surface of the semiconductor substrate SUB. The gate electrode GE is formed over the main surface of the semiconductor substrate SUB between the paired source/drain regions SD through the gate insulating film GI. The gate electrode GE may have a laminate structure which includes a first, conductive film GE1 and a second conductive film GE2. A silicide layer SBC may be formed on the surface of each of the paired source/drain regions SD.

The MOS transistor PTR for the peripheral circuit includes a pair of source/drain regions PSD, a gate insulating film GI, and a gate electrode GE.

The paired source/drain regions PSD are spaced from each other in the main surface of the semiconductor substrate SUB. The gate electrode GE is formed over the main surface of the semiconductor substrate SUB between the paired source/drain regions SD through the gate insulating film GI. The gate electrode GE may have a laminate structure which includes a first conductive film GE1 and a second conductive film GE2.

In each of the transistors for the SRAM memory cell and those for the peripheral circuit, an insulating film IL1 is formed over the gate electrode GE. The insulating film IL1 has a laminate structure which includes, for example, a silicon oxide film made of TEOS (Tetra Ethyl Ortho Silicate) and a silicon nitride film The insulating film IL1 functions as a stopper film for etching in the so-called self-alignment process in which the insulating film IL1 is used as a mask.

In each of the transistors for the SRAM memory cell and those for the peripheral circuit, sidewall insulating films SW are formed on the sidewalls of the gate insulating film GI, gate electrode GE and insulating film IL1. Each sidewall insulating film SW also functions as a stopper film for etching in the so-called self-alignment process in which the sidewall insulating film SW is used as a mask.

The insulating film IL1 is formed over the gate electrode GE and the gate electrode GE is electrically coupled to another wiring in a region extending toward the backside of the paper, which is not shown in the sectional view of FIG. 3.

The MONOS transistors MTR1 and MTR2 and MOS transistors TR1 to TR4 which constitute the two non-volatile memory parts NVP1 and NVP2 each have the same configuration as the transistors AC1, AC2, DR1, and DR2 for the SRAM memory cell.

The MONOS transistors MTR1 and MTR2 each include a gate insulating film with a charge capture part. Specifically, the gate insulating film of each of the MONOS transistors MTR1 and MTR2 is an ONO film which has a laminate structure comprised of a silicon oxide film, a silicon nitride film and a silicon oxide film

Since the configuration of each of the two non-volatile memory parts NVP1 and NVP2 is the same as that in the second embodiment which will be described later, it is not described here.

An interlayer insulating film II1 is formed over the semiconductor substrate SUB in a manner to cover the transistors for the SRAM memory cell, peripheral circuit, and non-volatile memory parts. In the SRAM memory cell formation region, the interlayer insulating film II1 over the source/drain regions SD and the gate electrode GE is selectively removed and plug conductive films SPP are formed in the areas where it has been removed.

An interlayer insulating film II2 is formed over the interlayer insulating film II1. In the SRAM memory cell formation region, through holes which reach the plug conductive films SPP are made in the interlayer insulating film II2. The bit line BL is formed over the interlayer insulating film II2 in a manner to be electrically coupled to the plug conductive films SPP through these through holes.

Furthermore, in the peripheral circuit formation region, a contact hole which reaches the source/drain regions SD and the gate electrode GE from the upper surface of the interlayer insulating film II2 is made. A conductive film ITC is buried in the contact hole. A wiring ITL is formed in a manner to be electrically coupled to the source/drain regions and the gate electrode GE through the conductive film ITC.

Interlayer insulating films II3 and II4, which are, for example, silicon oxide films, are sequentially formed in a manner to cover the hit line BL and wiring ITL. Furthermore, interlayer insulating films II5, II6, and II7, which are, for example, silicon oxide films, are sequentially formed in a manner to contact the upper surface of the interlayer insulating film II4.

A TFT electrode TE is formed over the interlayer insulating film II3. The TFT electrode TE is electrically coupled to the gate electrode GE of the driver transistor DR2 and the source/drain regions SD of the access transistor AC1, for example, through the plug conductive film SPP.

A TFT gate insulating film TGI is formed on the TFT electrode TE and a semiconductor Layer TL for TFT lies over the film TGI. The semiconductor layer TL for TFT is, for example, made of polycrystalline silicon. A channel formation region and a pair of source/drain regions which sandwich the channel formation region are formed in the semiconductor layer TL for TFT. The TFT electrodes TE and the semiconductor layers TL for TFT constitute the load transistors LO1 and LO2 as TFTs.

The interlayer insulating film II4 lies in a manner to cover the semiconductor layer TL for TFT. A through hole which penetrates through the semiconductor layer TL for TFT from the upper surface of the interlayer insulating film II4 and reaches the TFT electrode TE is made. A conductive film DC called a data node contact is buried in the through hole. The conductive film DC contacts the upper surface of the TFT electrode TE and also contacts the edge of the semiconductor layer TL for TFT and is exposed on the interlayer insulating film II4.

The data node contact DC is a conductive film to form a flip flop circuit (cross-coupled circuit) for the SRAM. The data node contact DC is, for example, made of polycrystalline silicon doped with impurities (doped polysilicon), like the gate electrode GE.

Capacitors CA1 and CA2 are formed over the interlayer insulating film II5. The capacitors CA1 and CA2 each include a storage node SN to serve as the lower electrode, a cell plate CP to serve as the upper electrode, and a capacitor dielectric film CI.

A trench which reaches the interlayer insulating film II4 from the upper surface of the interlayer insulating film II5 is made in the interlayer insulating film II5. The storage node SN is formed along the inner wall of the trench. The cell plate CP is formed in a manner to face the storage node SN with the capacitor dielectric film between them. The storage node SN of the capacitor CA1 contacts the upper surface of the data node contact. DB so that it is electrically coupled to the data node contact DB.

Metal wirings MIC are formed, for example, over the interlayer insulating film II6 and interlayer insulating film II7 above the capacitors CA1 and CA2. The metal wirings MIC are, for example, made of aluminum, aluminum-copper alloy, copper, or tungsten. Preferably the upper or lower surfaces of each metal wiring MIC are covered with barrier metal such as tantalum, titanium, or titanium nitride. Also it is preferable that coupling between the metal wirings MIC and coupling between a metal wiring MIC and the bit line BL be made, for example, by a metal contact conductive film MC of copper or tungsten.

A passivation film PSV is formed over the interlayer insulating film II7 in a manner to cover the metal wiring MIC over the interlayer insulating film II7.

Next, the effects of the first embodiment will be described in comparison with the comparative example shown in FIG. 4.

In the comparative example shown in FIG. 4, capacitors CA1 and CA2 are not provided. In the comparative example, a “full CMOS” transistor is configured. Specifically, in the comparative example, six transistors AC1, AC2 , DR1, DR2, LO1, and LO2 which constitute an SRAM memory cell are formed on the surface of the semiconductor substrate SUB.

In this comparative example, a soft error and a latch-up problem occur as follows.

A soft error is an error which randomly inverts the data inside the SRAM due to alpha rays and neutron rays entering the semiconductor substrate. In the SRAM memory cell of the comparative example shown in FIG. 4, when the cell size is smaller, the capacitance component stored in the memory cell decreases. As a result, the amount of charge required to invert the held data (critical charge amount) decreases and a slight noise inverts the held data. For this reason, as alpha rays and neutron rays enter the semiconductor substrate and collide against the atomic nucleus of elements, the generated charged ions induce a large amount of charge and thereby invert the held data, causing a soft error.

In contrast, in this embodiment, the capacitors CA1 and CA2 are coupled to the memory nodes N1 and N2 of the SRAM memory cell respectively as shown in FIG. 2. Consequently, the amount of charge required to invert the held data (critical charge amount) can be increased. Therefore, even if alpha rays and neutron rays enter the semiconductor substrate SUB, the held data is hardly inverted and occurrence of soft errors is suppressed.

A latch-up is a phenomenon that a PNPN structure as a parasitic thyristor structure is conducting and a large current flows between a power supply terminal and a grounding terminal. In the SRAM memory cell of the comparative example shown in FIG. 4, a CMOS transistor is formed on the surface of the semiconductor substrate. For this reason, the above latch-up problem occurs.

In contrast, in this embodiment, the load transistors LO1 and LO2 of the SRAM memory cell are TFTs as shown in FIG. 2. Therefore, the transistors formed on the surface of the semiconductor substrate SUB are only the access transistors AC1 and AC2 and driver transistors DR1 and DR2. The channels of the access transistors AC1 and AC2 and driver transistors DR1 and DR2 are of the same conductivity type. Therefore, in the SRAM memory cell, no CMOS transistor is formed on the surface of the semiconductor substrate SUB. Therefore, latch-ups attributable to a CMOS transistor can be prevented.

In the comparative example shown in FIG. 4, the six transistors AC1, AC2, DR1, DR2, LO1, and LO2 included in the SRAM memory cell part are formed on the surface of the semiconductor substrate SUB. For this reason, the plane area occupied by the SRAM memory cell is relatively large.

On the other hand, according to this embodiment, the load transistors LO1 and LO2 are TFTs. This means that among the transistors of the SRAM memory cell, only four transistors, namely the access transistors AC1 and AC2 and driver transistors DR1 and DR2, are formed on the semiconductor substrate. Therefore, the plane area occupied by the SRAM memory cell can be decreased.

In addition, in this embodiment, the SRAM memory cell has a flip flop circuit. The flip flop circuit eliminates the need for the so-called “refresh” process to restore the charge stored as information in a given cycle.

Furthermore, in this embodiment, during normal operation when the SRAM part SRP operates, high speed random access is possible. When the power is off, the data in the SRAM part SRP is written in the MONOS transistors MTR1 and MTR2 and when the power is turned back on, the data in the MONOS transistors MTR1 and MTR2 is restored in the SRAM part SRP. Thus the semiconductor device according to this embodiment functions as a non-volatile memory.

### Second Embodiment

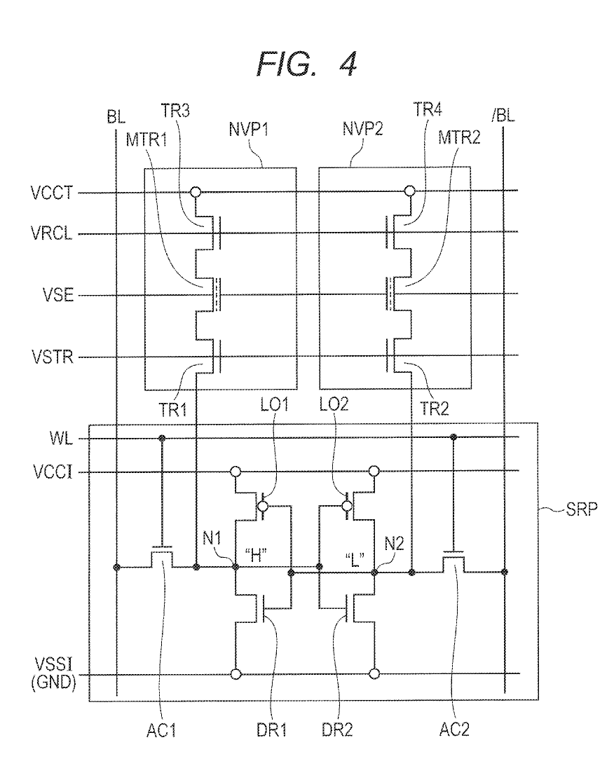

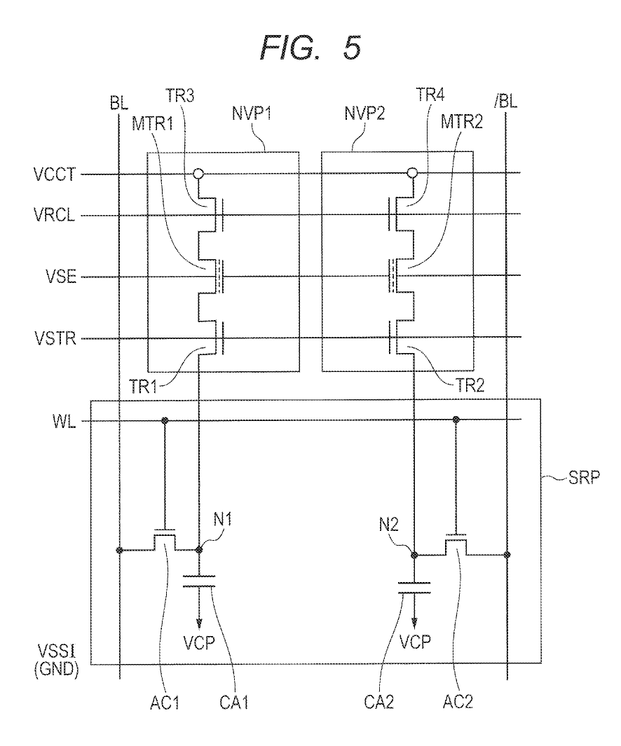

As shown in FIG. 5, the circuit configuration of the semiconductor device according to the second embodiment is different from the circuit configuration according to the first embodiment shown in FIG. 2 in that the flip flop circuit is eliminated.

In the memory cell according to the second embodiment, the circuit of the SRAM part SRP includes access transistors AC1 and AC2 and capacitors CA1 and CA2 and does not include driver transistors and load transistors. The memory cell according to the second embodiment includes a pseudo SRAM part SRP comprised of only the access transistors AC1 and AC2 and capacitors CA1 and CA2, and two non-volatile memory parts NVP1 and NVP2.

The other elements of the circuit configuration in the second embodiment are almost the same as in the first embodiment and in the second embodiment the same elements as in the first embodiment are designated by the same reference signs and their description is not repeated here.

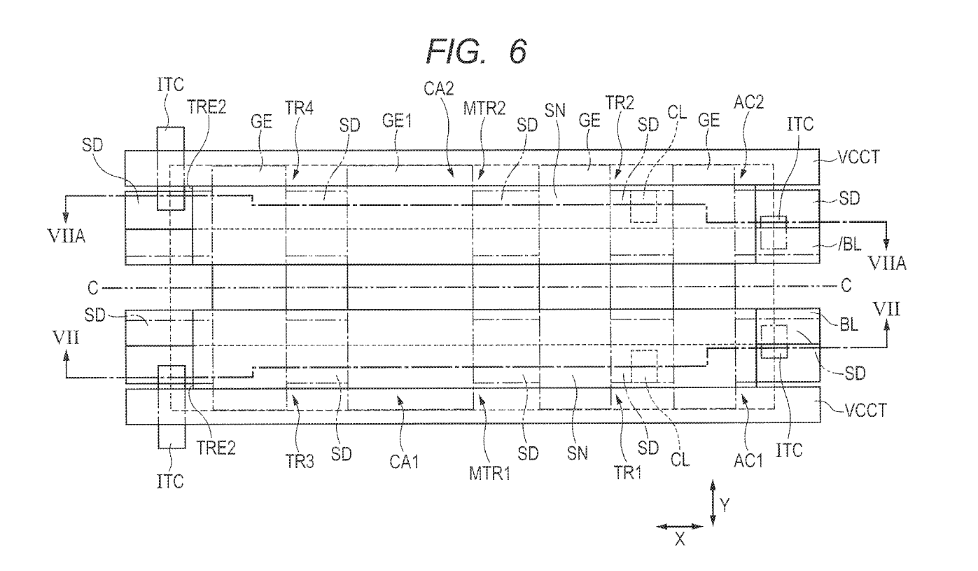

Next, the concrete configuration of the memory cell according to the second embodiment will be described referring to FIGS. 6 to 10.

As shown in FIG. 6, access transistors AC1 and AC2, MONOS transistors MTR1 and MTR2, and MOS transistors TR1 to TR4 are formed on the surface of the semiconductor substrate SUB.

The access transistor AC1, MONOS transistor MTR1, and MOS transistors TR1 and TR3 are arranged side by side in a first direction (X direction in the figure), making up a first transistor group. The access transistor AC2, MONOS transistor MTR2, and MOS transistors TR2 and TP4 are arranged side by side in the same direction as the first direction (X direction in the figure), making up a second transistor group.

The first transistor group and the second transistor group are adjacent to each other in the second direction (Y direction in the figure) orthogonal to the first direction (X direction) The first transistor group and the second transistor group are axially symmetric with respect to a virtual line (C-C) located between them in a plan view. Here, “plan view” means a view taken in the direction orthogonal to the surface of the semiconductor substrate SUB, as shown in FIG. 6.

The capacitor CA1 located above the first transistor group and the capacitor CA2 located above the second transistor group are adjacent to each other in the second direction (Y direction). The capacitors CA1 and CA2 are axially symmetric with respect to the virtual line (C-C) located between them in a plan view.

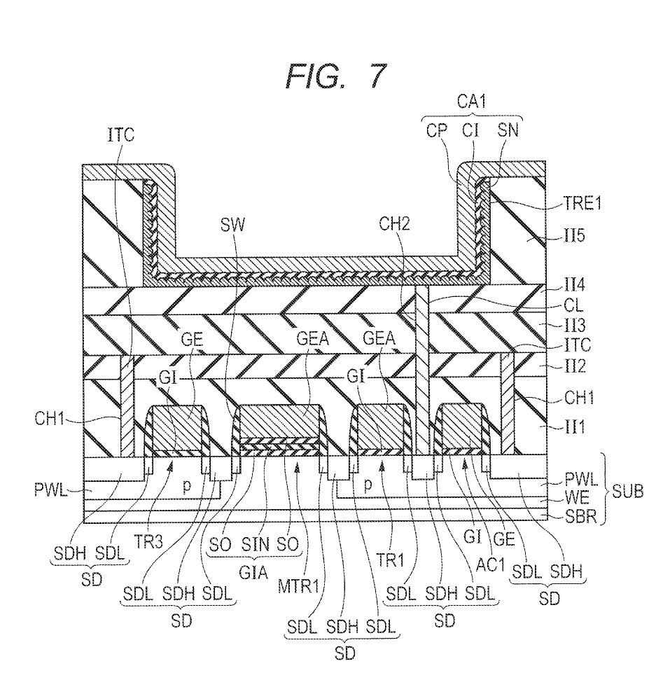

The cross section taken along the line VII-VII of FIG. 6 is structurally almost the same as the cross section taken along the line VIIA-VIIA of FIG. 6. Therefore, the typical sectional structure is explained below referring to FIG. 7 which shows the cross section taken along the line VII-VII, in which the explanation is given in the order from the lower layers to the upper layers.

As shown in FIG. 7, the semiconductor substrate SUB has a substrate region SBR and a p-type well region WE formed over the substrate region SBR. A p-type region PWL is formed in the surface of the semiconductor substrate SUB. The access transistors AC1 and AC2, MONOS transistors MTR1 and MTR2, and MOS transistors TR1 to TR4 are formed on the surface of the semiconductor substrate SUB in which the p-type region PWL is formed.

The two MONOS transistors MTR1 and MTR2 each include a pair of source/drain regions SD, a gate insulating film GIA, and a gate electrode GEA. The paired source/drain regions SD are spaced from each other in the surface of the semiconductor substrate SUB.

The six transistors other than the MONOS transistors each have a pair of source/drain regions SD, a gate insulating film GI, and a gate electrode GE. The paired source/drain regions SD are spaced from each other in the surface of the semiconductor substrate SUB.

One of the paired source/drain regions of the MONOS transistor MTR1 is formed from the same impurity region as one of the paired source/drain regions of the MOS transistor TR1. The other of the paired source/drain regions of the MONOS transistor MTR1 is formed from the same impurity region as one of the paired source/drain regions of the MOS transistor TR3. The other of the paired source/drain regions of the MOS transistor MTR1 is formed from the same impurity region as one of the paired source/drain regions of the access transistor AC1.

Though not shown in the figure, one of the paired source/drain regions of the MONOS transistor MTR2 is formed from the same impurity region as one of the paired source/drain regions of the MOS transistor TR2. The other of the paired source/drain regions of the MONOS transistor MTR2 is formed from the same impurity region as one of the paired source/drain regions of the MOS transistor TR4. The other of the paired source/drain regions of the MOS transistor MTR2 is formed from the same impurity region as one of the paired source/drain regions of the access transistor AC2.

These source/drain regions SD each have an LDD (Lightly Doped Drain) structure which includes a high concentration impurity region SDH and a low concentration impurity region SDL.

The gate electrode GEA of each of the two MONOS transistors MTR1 and MTR2 is formed over a region between the paired source/drain regions through the gate insulating film GIA. The gate insulating film GIA of each of the MONOS transistors MTR1 and MTr2 is an ONO film in which a silicon oxide film SO, a silicon nitride film SIN, and a silicon oxide film SO are stacked. The silicon nitride film SIN of the ONO film functions as a charge capture part.

The gate electrode GE of each of the six transistors other than the MONOS transistors is formed over a region between the paired source/drain regions through a gate insulating film GI. The gate insulating film GI of each of the transistors AC1, AC2 and TR1 to TR4 other than the MONOS transistors is, for example, a silicon oxide film

For example, the gate electrodes GEA and GE of the eight transistors may be formed from a doped polysilicon layer. Instead, the gate electrodes GEA and GE of the eight transistors may each have a multilayer structure which includes a first conductive film GE1 and a second conductive film GE2 as shown in FIG. 3.

Sidewall insulating films SW are formed in a manner to cover the sidewalls of the gate electrodes GEA and GE and the gate insulating films GIA and GI of the eight transistors.

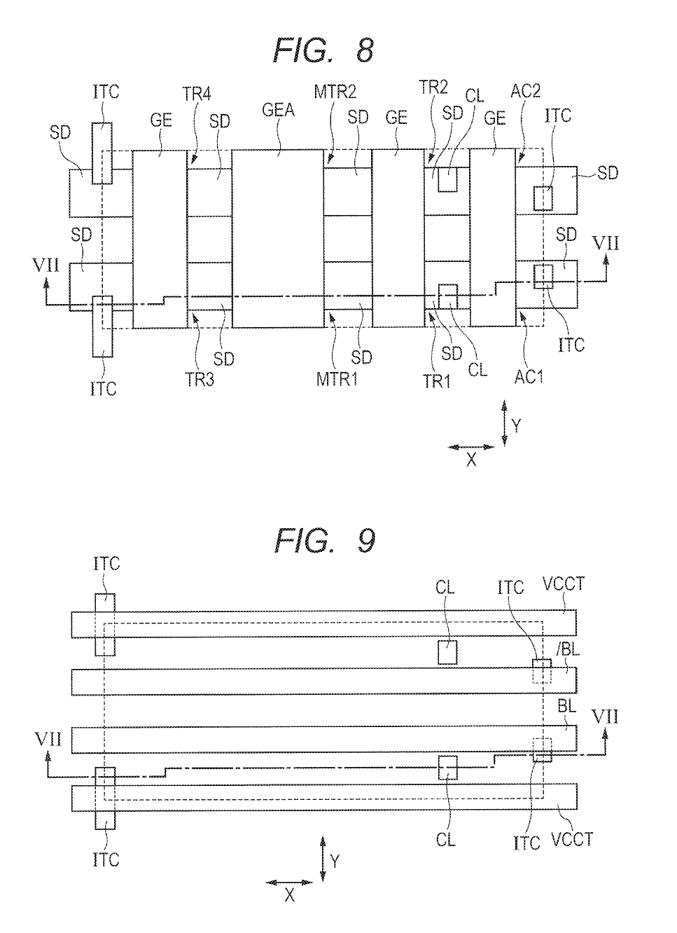

As shown in FIG. 8, the gate electrode GEA of the MONOS transistor MTR1 and the gate electrode GEA of the MONOS transistor MTR2 are made of the same conductive film Also, the gate electrode GE of the MOS transistor TR1 and the gate electrode GE of the MOS transistor TR2 are made of the same conductive film

Also, the gate electrode GE of the MOS transistor TR3 and the gate electrode GE of the MOS transistor TR4 are made of the same conductive film Also, the gate electrode GE of the access transistor AC1 and the gate electrode GE of the access transistor AC2 are made of the same conductive film These gate electrodes GE extend in the second direction (Y direction in the figure).

As shown in FIG. 7, interlayer insulating films II1 and II2 are formed over the surface of the semiconductor substrate SUB sequentially in a manner to cover the eight transistors. Contact holes CH1 are made in a manner to reach the source/drain region SD of the MOS transistor TR3 and the source/drain region SD of the access transistor AC1 from the upper surface of the interlayer insulating film II2.

A conductive film ITC is formed in a manner to be buried in each of the contact holes CH1. A wiring VCCT (FIG. 9) which is electrically coupled to the source/drain region SD of the MOS transistor TR3 through the conductive film ITC is formed over the interlayer insulating film II2. Also, a bit line BL (FIG. 9) which is electrically coupled to the source/drain region SD of the access transistor AC1 through the conductive film ITC is formed over the interlayer insulating film II2.

Although not shown, contact holes are made in a manner to reach the source/drain region SD of the MOS transistor TR4 and the source/drain region SD of the access transistors AC2 from the upper surfaces of the interlayer insulating films II1 and II2. Conductive films are also buried in these contact holes.

A wiring VCCT (FIG. 9) which is electrically coupled to the source/drain region SD of the MOS transistor TR4 through the conductive film in the contact hole is formed over the interlayer insulating film II2. Also, a bit line/BL (FIG. 9) which is electrically coupled to the source/drain region SD of the access transistor AC2 through the conductive film in the contact hole is formed over the interlayer insulating film II2.

As shown in FIG. 9, the bit line BL is electrically coupled to the source/drain region SD of the access transistor AC1 through the conductive film ITC. The bit line/BL is electrically coupled to the source/drain region SD of the access transistor AC2 through the conductive film ITC.

The wiring VCCT is electrically coupled to the source/drain region SD of the MOS transistor TR3 through the conductive film ITC. The wiring VCCT is electrically coupled to the source/drain region SD of the MOS transistor TR4 through the conductive film ITC.

The two bit lines BL and/BL and the two wirings VCCT extend in the first direction (X direction in the figure) crossing (for example, orthogonal to) the direction in which the gate electrodes GE shown in FIG. 8 extend and they are parallel to each other.

As shown in FIG. 7, interlayer insulating films II3, II4, and II5 are formed over the interlayer insulating film II2 sequentially in a manner to cover the bit lines BL and/BL and the wirings VCCT. A first trench TRE1 which reaches the upper surface of the interlayer insulating film II4 is made in the interlayer insulating film II5. The first trench TRE1 is located above all the regions of the MONOS transistor MTR1, MOS transistors TR1 and TR3, and access transistor AC1.

A contact hole CH2 is made in a manner to reach the source/drain region SD of the MOS transistor TR1 (source/drain region SD of the access transistor AC1) from the upper surface of the interlayer insulating film II4 exposed from the first trench TRE1. A conductive film CL is formed in a manner to be buried in the contact hole CH2. The conductive film CL is electrically coupled to the source/drain region SD of the MOS transistor TR1 (source/drain region SD of the access transistor AC1).

A capacitor CA1 is formed in a manner to be electrically coupled to the source/drain region SD of the MOS transistor TR1 (source/drain region SD of the access transistor AC1) through the conductive film CL. The capacitor CA1 includes a storage node SN, a capacitor dielectric film CI, and a cell plate CP.

The storage node SN is formed along the inner wall of the first trench TRE1 in a manner to contact the conductive film CL. The cell plate CP is formed in a manner to face the storage node SN through the capacitor dielectric film CI. The storage node SN is located above all the regions of the MONOS transistor MTR1, MOS transistors TR1 and TR3, and access transistor AC1.

As shown in FIGS. 6 and 10, a second trench TRE2 which reaches the upper surface of the interlayer insulating film II4 is made in the interlayer insulating film II5. The second trench TRE2 is located above all the regions of the MONOS transistor MTR2, MOS transistors TR2 and TR4, and access transistor AC2.

A contact hole is made in a manner to reach the source/drain region SD of the MOS transistor TR2 (source/drain region SD of the access transistor AC2) from the upper surface of the interlayer insulating film II4 exposed from the second trench TRE2. A conductive film CL is formed in a manner to be buried in the contact hole. The conductive film CL is electrically coupled to the source/drain region SD of the MOS transistor TR2 (source/drain region SD of the access transistor AC2).

A capacitor CA2 is formed in a manner to be electrically coupled to the source/drain region SD of the MOS transistor TR2 (source/drain region SD of the access transistor AC2) through the conductive film CL. The capacitor CA2 includes a storage node SN, a capacitor dielectric film CI, and a cell late CP.

The storage node SN is formed along the inner wall of the second trench TRE2 in a manner to contact the conductive film CL. The cell plate CP is formed in a manner to face the storage node SN through the capacitor dielectric film CI. The storage node SN is located above all the regions of the is M0NOS transistor MTR2, MOS transistors TR2 and TR4, and access transistor AC2.

The storage node SN of the capacitor CA1 and the storage node SN of the capacitor CA2 are adjacent to each other in the second direction (Y direction). The surfaces of the storage nodes SN of the capacitors CA1 and CA2 may be roughened in order to increase the capacitor capacitance.

Next, how the semiconductor device according to the second embodiment operates will be described referring to FIGS. 5, 11, and 12.

First, normal operation is explained below.

As shown in FIG. 5, during normal operation, only the pseudo SRAM part SRP operates while all the transistors MTR1, MTR2, and TR1 to TR4 of the two non-volatile memory parts NVP1 and NVP2 are off. Specifically, the bit lines BL and/BL have High and Low potentials and when the word line WL is activated, High and Low data are written in the first memory node N1 and the second memory node N2.

In reading data, by activating the word line WL with both the bit lines BL and/BL at 0 V, the current which flows from the memory node where High data has been written is read by a latch-type sense amplifier coupled to the bit lines BL and/BL.

Since the potential of the memory node where High data has been written goes down due to data reading, the data is rewritten (restored) after data reading. Also, the potential of the memory node where High data has been written goes down due to leakage current, the data must be rewritten (refreshed) periodically.

This normal operation is not unique to the memory cell in this embodiment but it is the same as operation of an ordinary pseudo SRAM.

Next, how the semiconductor device operates when the power is off will be described.

When the power is off, the data in the pseudo SRAM part SRP is written in the non-volatile memory parts NVP1 and NVP2.

First, before the data in the first and second memory nodes N1 and N2 of the pseudo SRAM part SRP is written in the MONOS transistors MTR1 and MTR2, the threshold voltage Vth of the MONOS transistors MTR1 and MTR2 is initialized. Specifically, when the MOS transistors TR1 to TR4 coupled to the source/drain regions of the MONOS transistors MTR1 and MTR2 are off, for example, a voltage of −10 V is applied to the gate electrodes of the MONOS transistors MTR1 and MTR2 for 3 msec. Consequently the threshold voltage Vth of the MONOS transistors MTR1 and MTR2 is set to −1.0 V.

Next, the data from the pseudo SRAM part SRP is written in the MONOS transistors MTR1 and is MR2 of the non-volatile memory parts NVP1 and NVP2. Specifically, with the word line WL of the pseudo SRAM part SRP off, the MOS transistors TR1 and TR2 of the non-volatile memory parts NVP1 and NVP2 are turned on and, for example, a voltage of +12 V is applied to the gate electrodes of the MONOS transistors MTR1 and MTR2. The voltage of the first memory node N1 of the pseudo SRAM part SRP and the voltage of the second memory node N2 of the pseudo SRAM part SRP are applied to the drains of the MONOS transistors MTR1 and MTR2, respectively. For example, if the potential of the memory node for High data is 2.0 V, the gate potential of the MONOS transistor coupled to the memory node for High data is 10 V and the gate potential of the MONOS transistor coupled to the memory node for tow data is 12 V.

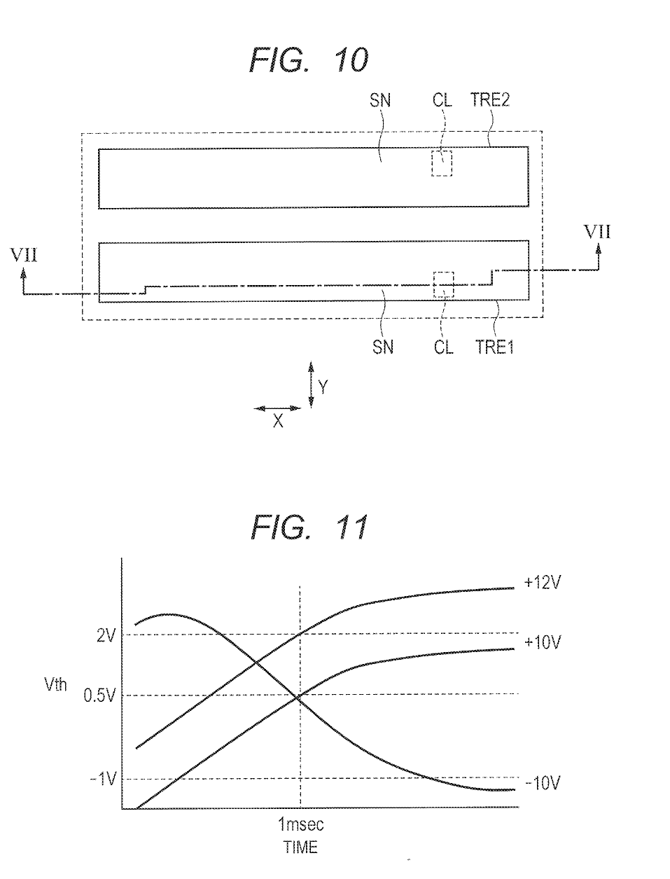

As shown in FIG. 11, if writing is done for 1 msec, in the MONOS transistor which is coupled to the memory node for High data and to which a gate voltage of 10 V is applied, the threshold voltage Vth is 0.5 V. On the other hand, in the MONOS transistor which is coupled to the memory node for Low data and to which a gate voltage of 12 V is applied, the threshold voltage Vth is 2.0 V.

While data is being written in the MONOS transistor, the potential of the memory node for High data goes down. However, since the time of data writing in the M0NOS transistor is one order of magnitude shorter than the data rewriting cycle time in normal operation (for example, 10 msec), the decrease in the potential of the memory node for High data is not a problem.

The decrease in the potential of the memory node depends on the off-leakage current and capacitor capacitance of the

MONOS transistor. Therefore, the decrease in the potential of the memory node can be further improved by improving the off-leakage current and capacitor capacitance of the MOS transistor.

Next, how the semiconductor device operates when the power is on will be described.

When the power is on, the data written in the MONOS transistors MTR1 and MTR2 of the non-volatile memory parts NVP1 and NVP2 must be rewritten in the pseudo SRAM part SRP. After the power is turned on, first the pseudo SRAM part SPP is initialized and Low data is written in both the first memory node N1 and the second memory node N2. Then, with the word line WL of the pseudo SRAM part SRP closed, the MONOS transistors MTR1 and MTR2 and the MOS transistors TR1 and TR2 are turned on.

At this time, the voltage applied to the gate electrodes of the MONOS transistors MTR1 and MTR2 is higher than the threshold voltage Vth of the MONOS transistor coupled to the memory node for High data of the pseudo SRAM part SRP and lower than the threshold voltage Vth of the MONOS transistor coupled to the memory node for Low data. For example, if the threshold voltages Vth of the MONOS transistors are 0.5 V and 2.0 V, the voltage applied to the gate electrodes of the MONOS transistors MTR1 and MTR2 is 1.0 V.

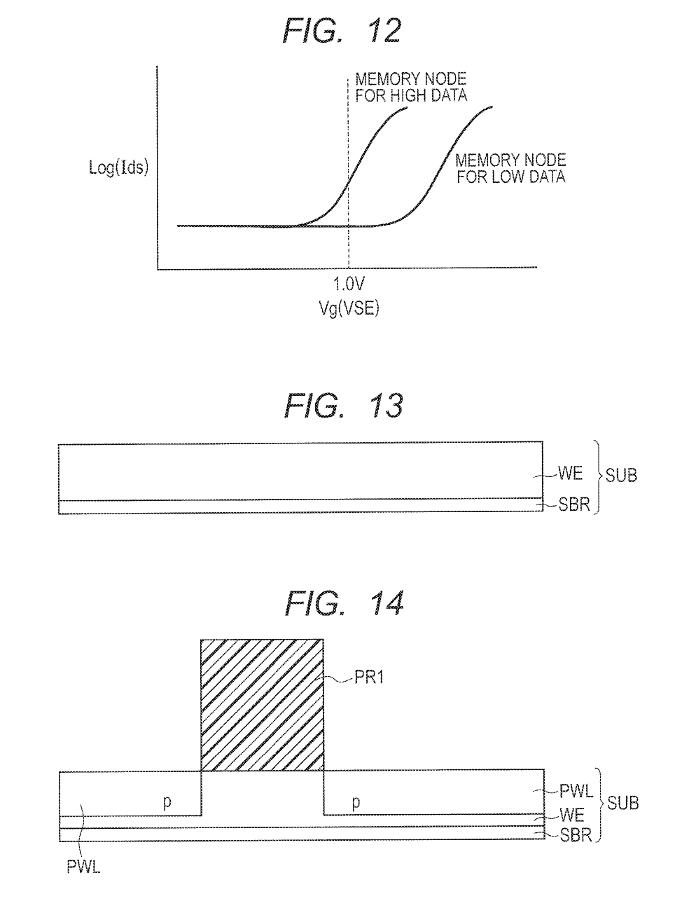

As shown in FIG. 12, if the voltage applied to the gate electrodes is 1.0 V, a current flows in the MONOS transistor coupled to the memory node for High data of the pseudo SRAM part SRP but a current does not flow in the MONOS transistor coupled to the memory node for Low data. Therefore, a current flows only in the MONOS transistor coupled to the memory node for High data of the pseudo SRAM part SRP and the High data is written from the MONOS transistor into the memory node of the pseudo SRAM part SRP.

After the data is written from the non-volatile memory parts NVP1 and NVP2 into the pseudo SRAM part SRP, reading and rewriting (refreshing) of the data is done and then normal operation of the pseudo SRAM part SRP is performed.

Next, the method for manufacturing the semiconductor device according to the second embodiment will be described referring to FIGS. 7 and 13 to 27.

As shown in FIG. 13, a p-type well region WE is formed in the semiconductor substrate SUB, for example, of silicon by ion implantation or the like. The ion implantation for the formation of the p-type well region WE is also used to adjust the threshold voltages Vth of the MONOS transistors.

As shown in FIG. 14, a resist pattern PR1 which covers the area for the formation of a MONOS transistor is made by a usual photoengraving technique. Then, a p-type region PWL is formed by ion implantation or the like, using the resist pattern PR1 as a mask. The threshold voltages Vth of transistors other than MONOS transistors are adjusted by the formation of the p-type region PWL. After that, the resist pattern PR1 is removed by ashinq or the like.

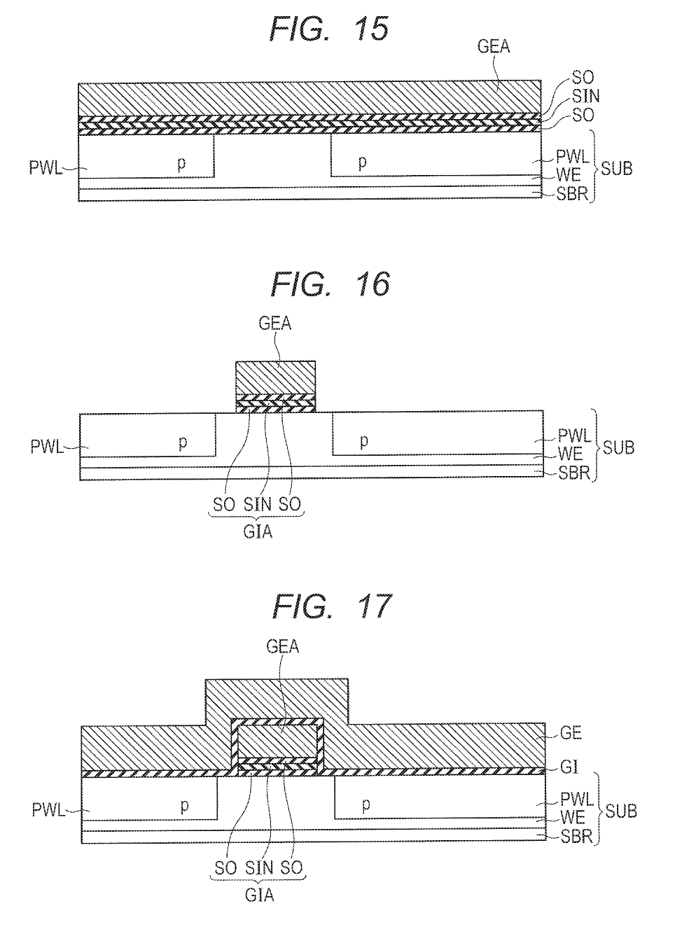

As shown in FIG. 15, an ONO film which includes a silicon oxide film SO, a silicon nitride film SIN, and a silicon oxide film SO is formed over the surface of the semiconductor substrate SUB. A conductive film GEA, for example, of polycrystalline silicon is formed over the ONO film

The ONO film is to become the gate insulating film of the MONOS transistor and the conductive film GEA is to become the gate electrode of the MONOS transistor. The conductive film GEA may be a doped silicon film obtained by implanting impurities into non-doped polycrystalline silicon after film formation or a doped polysilicon film obtained by doping phosphorous or the like during film formation.

After that, patterning is done on the conductive film GEA and ONO film by a usual photoengraving technique and an etching technique.

As shown in FIG. 16, as a result of the patterning process, the ONO film to become the gate insulating film GIA of the MONOS transistor and the gate electrode GEA of the MONOS transistor are formed.

As shown in FIG. 17, an insulating film GI, which is, for example, a silicon oxide film, is formed in a manner to cover the surface of the semiconductor substrate SUB and the gate electrode GEA of the MONOS transistor. Then, a conductive film GE, for example, of doped polysilicon is formed over the insulating film GI. The conductive film GE may be a doped silicon film obtained by implanting impurities into non-doped polycrystalline silicon after film formation or a doped polysilicon film obtained by doping phosphorous or the like during film formation.

The insulating film GI which covers the gate electrode GEA is to become the gate insulating film or the transistors other than the MONOS transistor. The conductive film GE which overlies and covers the gate electrode GEA is to become the gate electrode for the transistors other than the MONOS transistor.

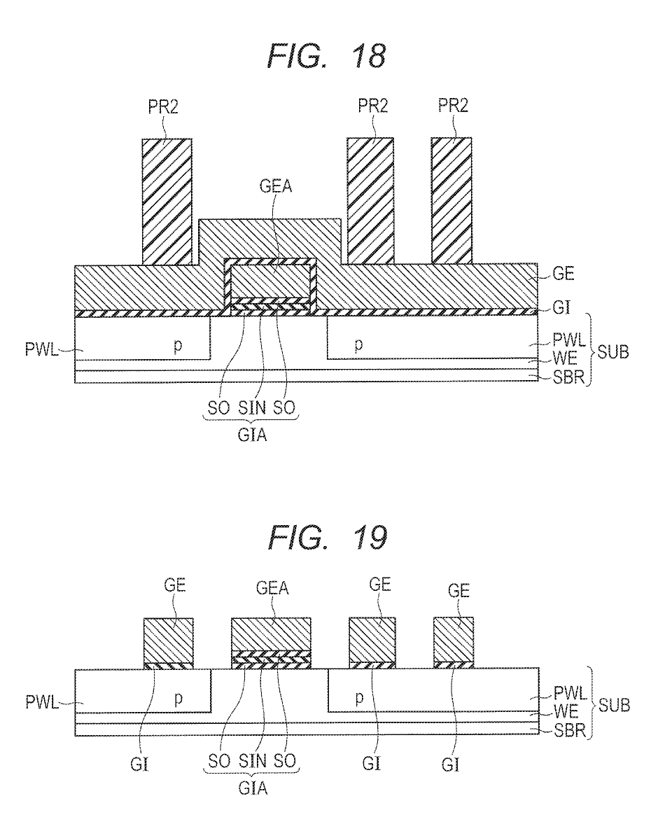

As shown in FIG. 18, a resist pattern PR2 is made by a usual photoengraving technique. The resist pattern PR2 serves as a mask for forming the gate electrodes of the transistors other than the MONOS transistor. The conductive film GE and the insulating film GI are selectively removed by dry etching or the like, using the resist pattern PR2 as a mask. After that, the resist pattern PR1 is removed by ashing or the like.

As shown in FIG. 19, as a result of the above etching process, the gate insulating films GI and gate electrodes GE of the transistors other than the MONOS transistor are formed. Since the gate electrode GEA of the MONOS transistor is covered with the insulating film GI, it is not etched during etching for forming the gate electrodes GE of the transistors other than the MONOS transistor. The conductive film GE in the form of a sidewall spacer remains on the sidewall of the gate electrode GEA of the MONOS transistor. The conductive film GE in the form of a sidewall spacer is removed by isotropic dry etching or the like.

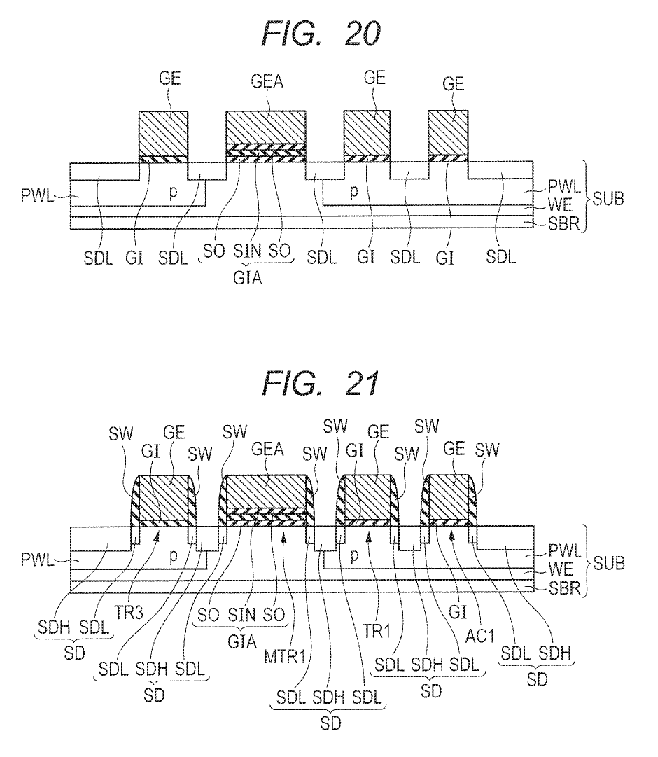

As shown in FIG. 20, impurities are introduced into the surface of the semiconductor substrate SUB by ion implantation or the like, using the gate electrodes GEA and GE as a mask. Consequently, a low concentration impurity region SDL which constitutes a transistor LDD structure is formed in the surface of the semiconductor substrate SUB.

As shown in FIG. 21, sidewall insulating films SW are formed on the sidewalls of the gate electrodes GEA and GE. The sidewall insulating films are, for example, silicon nitride films. After that, impurities are introduced into the surface of the semiconductor substrate SUB by ion implantation or the like, using the gate electrodes GEA and GE and the sidewall insulating films SW as a mask. Consequently, a high concentration impurity region SDH is formed in the surface of the semiconductor substrate SUB. The high concentration impurity region SDH and low concentration impurity region SDL constitute a source/drain region with an LDD structure.

After that, in order to reduce the sheet resistance of the gate electrodes GEA and GE, silicide such as cobalt silicide or nickel silicide may be formed over each gate electrode GE.

By taking the above steps, a MONOS transistor MTR1, MOS transistors TR1 and TR3, and an access transistor AC1 are formed. A MONOS transistor MTR2, MOS transistors TR2 and TR4, and an access transistor AC2 are also formed in the same manner as above, though not shown.

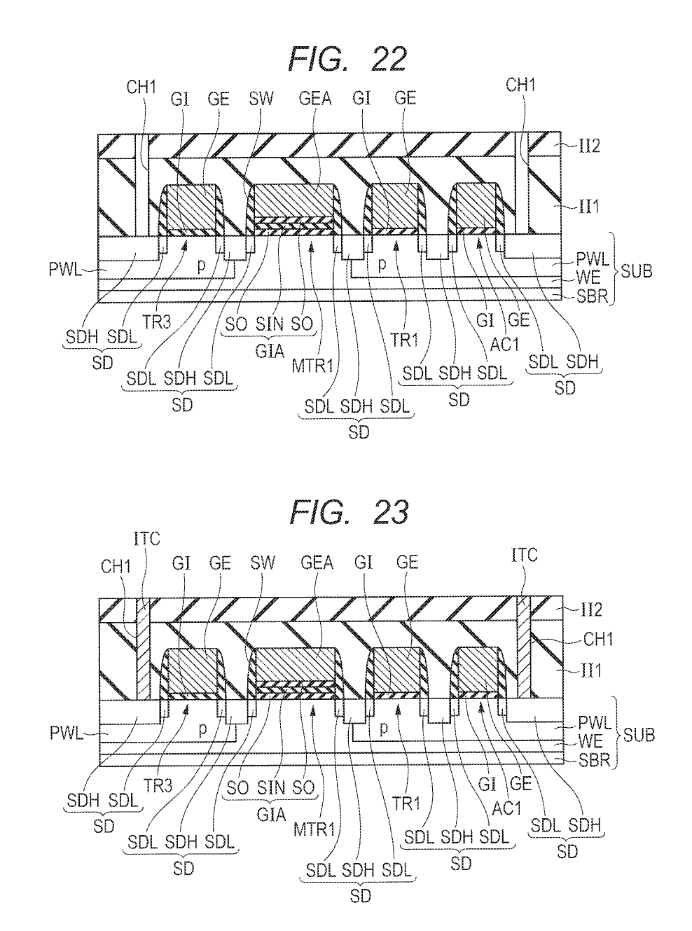

As shown in FIG. 22, an interlayer insulating film II1, which is, for example, a silicon oxide film, is formed over the surface of the semiconductor substrate SUB in a manner to cover the transistors MTR1, MTR2, TR1 to TR4, AC1, and AC2. After that, contact holes CH1 are made in the interlayer insulating films II1 and II2 by a usual photoengraving technique and an etching technique. The contact holes CH1 include a contact hole CH1 which reaches the source/drain region SD of the access transistor AC1 from the upper surface of the interlayer insulating film II2 and a contact hole CH1 which reaches the source/drain region SD of the MOS transistor TR3 from the upper surface of the interlayer insulating film II2.

Though not shown, a contact hole which reaches the source/drain region SD of the access transistor AC2 from the upper surface of the interlayer insulating film II2 and a contact hole which reaches the source/drain region SD of the MOS transistor TR4 from the upper surface of the interlayer insulating film II2 are also made at the same time.

As shown in FIG. 23, a conductive film ITC is formed in a manner to be buried I n each of the plural contact holes CH1. Two bit lines BL and/BL and two wirings VCCT as shown in FIG. 9 are made over the interlayer insulating film II2 in a manner to be electrically coupled to these conductive fi ms ITC.

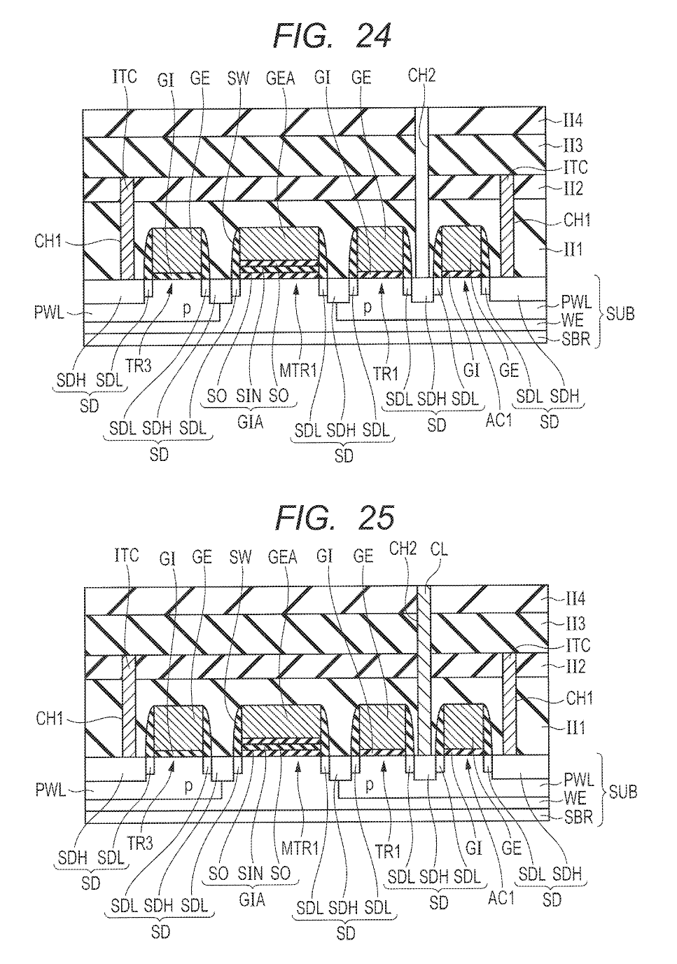

As shown in FIG. 24, interlayer insulating films II3 and II4 which are, for example, silicon oxide films are formed in the order of mention over the interlayer insulating film II2 in a manner to cover the bit lines BL and/BL and wirings VCCT. After that, a contact hole CH2 is made in the interlayer insulating films II1 to II4 by a usual photoengraving technique and an etching technique. The contact hole CH2 is made to reach the source/drain region SD of the MOS transistor TR1 (source/drain region SD of the access transistor AC1) from the upper surface of the interlayer insulating film II4.

Though not shown, a contact hole which reaches the source/drain region SD of the MOS transistor TR2 (source/drain region SD of the access transistor AC2) from the upper surface of the interlayer insulating film II4 is also made at the same time.

As shown in FIG. 25, a conductive film CL is buried in the contact hole CH2. The conductive film CL is made of metal such as doped silicon or tungsten (W).

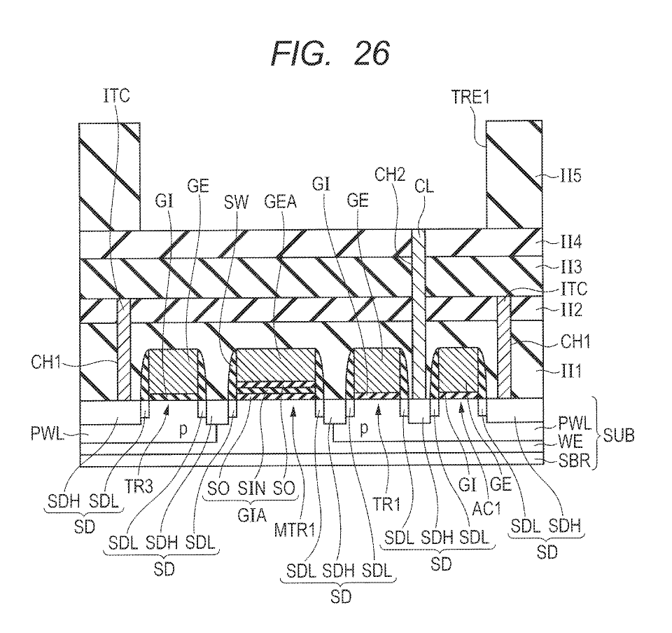

As shown in FIG. 26, an interlayer insulating film II5, which is, for example, a con oxide film, is formed over the interlayer insulating film II4. Then, a trench TRE1 which reaches the upper surface of the interlayer insulating film II4 is made in the interlayer insulating film II5 by a usual photoengraving technique and an etching technique. The upper surface of the conductive film CL is exposed on the bottom of the trench TRE1.

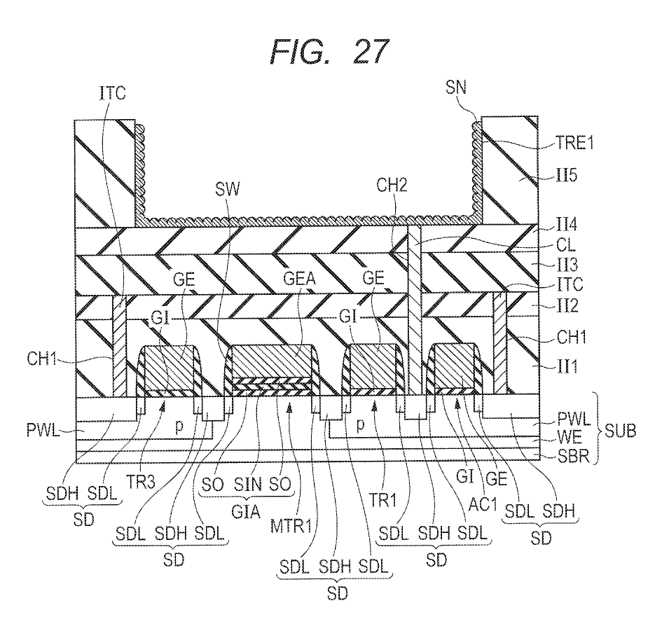

As shown in FIG. 27, a capacitor storage node SN is formed along the inner wall of the trench TRE1. The storage node SN is formed in a manner to be electrically coupled to the conductive film CL. The storage node SN may be subjected to a roughening process to have a rough surface.

As shown in FIG. 7, a capacitor dielectric film CI is formed in a manner to cover the storage node SN. A cell plate CP is formed in a manner to face the storage node SN through the capacitor dielectric film CI. The storage node SN, capacitor dielectric film CI, and cell plate CP make up a capacitor CA1.

Though not shown, a capacitor CA2 is also formed in the same way as the capacitor CA1. The method for forming a capacitor for an ordinary DRAM (Dynamic Random Access Memory) may be used to form the capacitors CA1 and CA2. The materials of the storage node SN, capacitor dielectric film CI, and cell plate CP differ depending on the kind of capacitor to be used, for example, a MIS capacitor, or MIM capacitor. After the memory cell part is thus formed, an interlayer insulating film which is an oxide film or the like is formed and wirings required for the peripheral circuit are made of aluminum (Al), copper (Cu) or the like.

By taking the above steps, the semiconductor device according to the second embodiment as shown in FIG. 7 is completed.

Next, the effects of the semiconductor device according to the second embodiment will be described.

As compared with the comparative example shown in FIG. 4, the flip flop circuit is eliminated in this embodiment. Therefore, latch-ups attributable to a CMOS transistor can be prevented.

Furthermore, since the memory cell has capacitors CA1 and CA2, occurrence of soft errors can be suppressed as in the first embodiment.

Furthermore, since no flip flop circuit is provided, the plane area occupied by the memory cell can be further decreased while soft errors are prevented and latch-ups are suppressed.

As shown in FIGS. 6 and 7, the capacitors CA1 and CA2 are located just above the non-volatile memory parts. Therefore, the area where the storage node SN and the cell plate CP face each other in each of the capacitors CA1 and CA2 can be increased. Consequently, the capacitance of the capacitors CA1 and CA2 is increased and operation of the memory cell can be stabilized.

### Third Embodiment

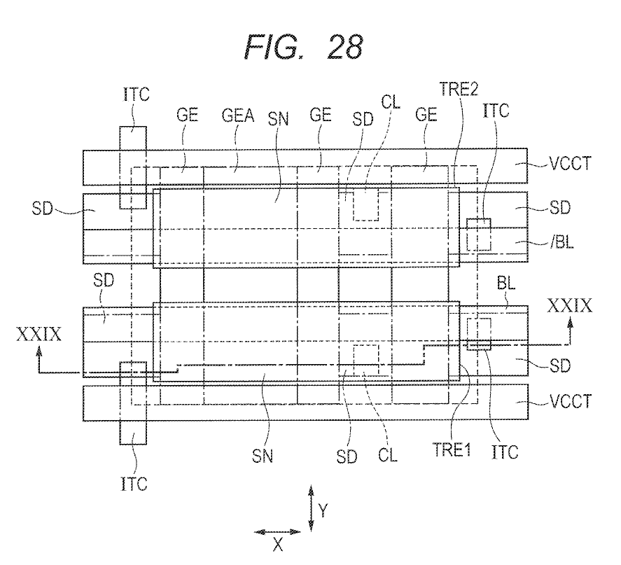

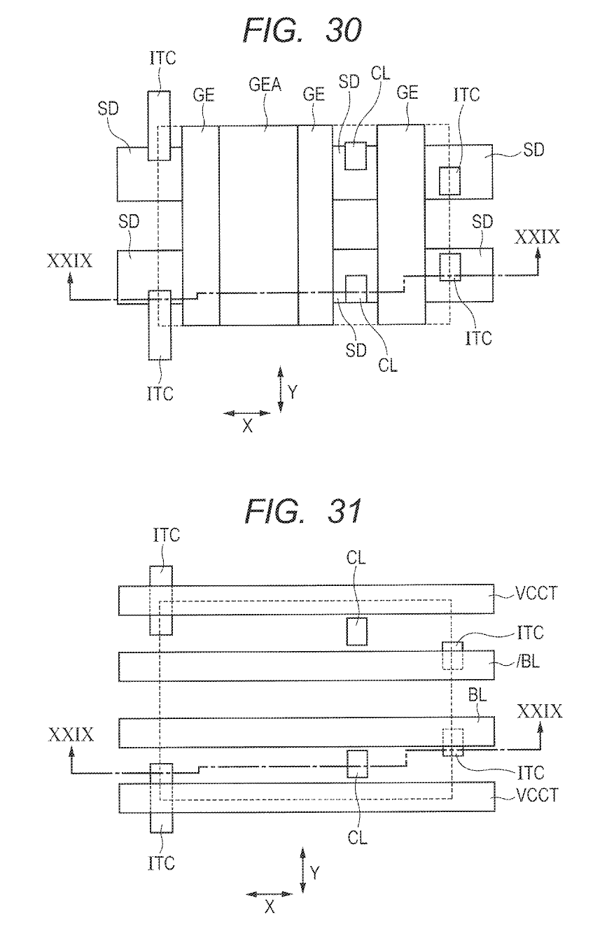

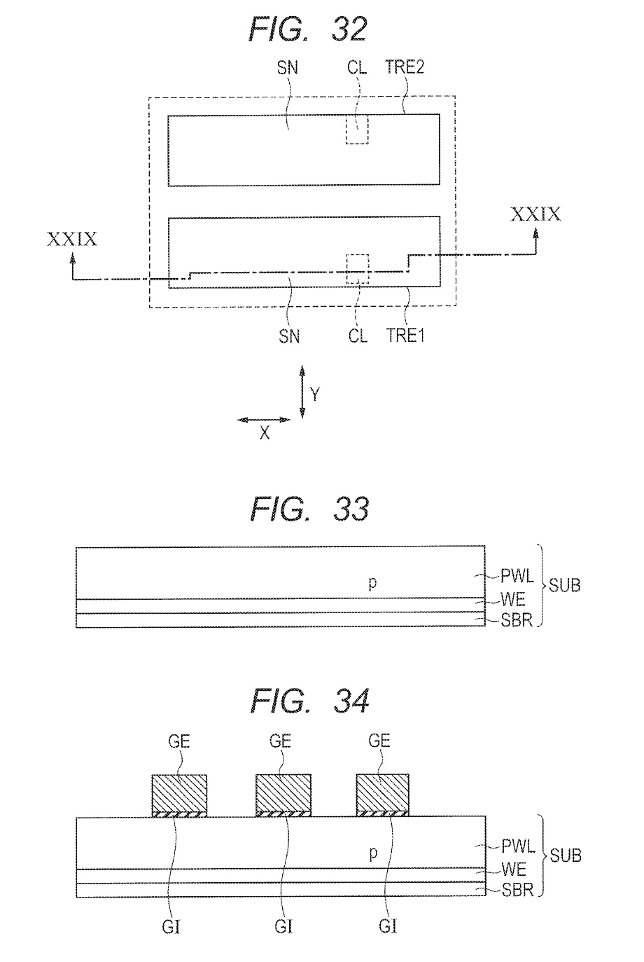

As shown in FIGS. 28 to 32, the semiconductor device according to the third embodiment is different from the second embodiment shown in FIGS. 6 to 10 in the structure of MONOS elements MTR1 and MTR2.

In this embodiment, the MONOS elements MTR1 and MTR2 each include an impurity region IR, a gate insulating film GIA, and a gate electrode GEA. The impurity region IR is formed in the surface of the semiconductor substrate SU which is sandwiched between the gate electrodes GE of the MOS transistors TR1 and TR3. The impurity region IR is a layer which is intended to adjust the threshold voltage Vth of each of the MONOS elements MTR1 and MTR2.

The gate electrode GEA is located in a manner to face the impurity region IR through the gate insulating film GIA.

The gate insulating film GIA is an ONO film which includes a silicon oxide film SO, a silicon nitride film SIN, and a silicon oxide film SO. The silicon nitride film SIN of the gate insulating film GIA functions as a charge capture part. The gate insulating film GIA is in direct contact with the side surfaces and upper surfaces of the gate electrodes GE of the MOS transistors TR1 and TR3.

The gate electrode GEA is located just above the gate electrodes GE of the MOS transistors TR1 and TR3 with the gate insulating film as an ONO film between them.

The other elements in the third embodiment are almost the same as in the second embodiment and in the third embodiment the same elements as in the second embodiment are designated by the same reference signs and their description is not repeated here. The way the semiconductor device according to the third embodiment operates is the same as in the second embodiment.

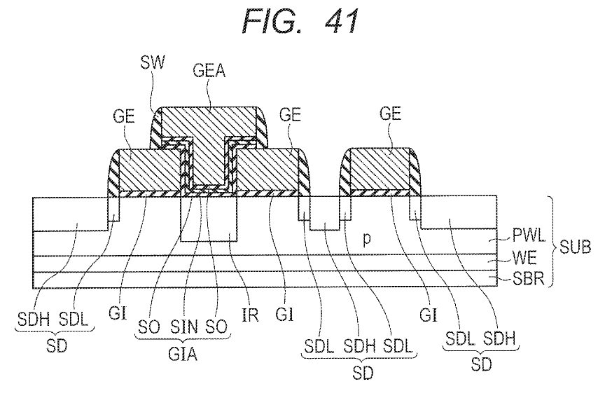

Next, the method for manufacturing the semiconductor device according to the third embodiment will be described referring to FIGS. 33 to 41.

As shown in FIG. 33, a p-type region PWL is formed in the semiconductor substrate SUB with a p-type well region. WE by ion implantation or the like. The threshold voltages Vth of the transistors other than the MONOS elements are adjusted by the formation of the p-type region PWL.

As shown in FIG. 34, an insulating film GI, which is, for example, a silicon oxide film, is formed in a manner to cover the surface of the semiconductor substrate SUB. A conductive film GE, for example, of doped polysilicon is formed over the insulating film GI. The conductive film GE may be a doped polysilicon film obtained by implanting impurities into non-doped polycrystalline silicon after film formation or a doped polysilicon film obtained by doping phosphorous or the like during film formation.

The insulating film GI is to become the gate insulating film of the transistors other than the MONOS elements. The conductive film GE is to become the gate electrodes of the transistors other than the MONOS elements.

Patterning is done on the conductive film GE and the insulating film GI by a usual photoengraving technique and a dry etching technique so that the gate electrodes GE and gate insulating films GI of the transistors other than the MONOS elements are formed.

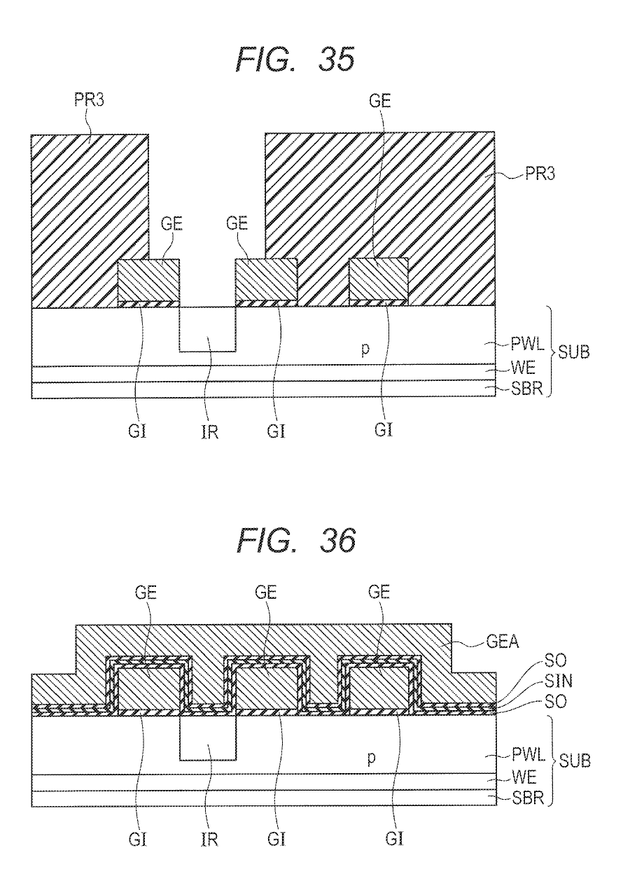

As shown in FIG. 35, a resist pattern PR3 is made by a usual photoengraving technique. The resist pattern PR3 has an opening in an area where a MONOS element is to be formed. After that, using the resist pattern PR3 as a mask, ion implantation is performed in order to adjust the threshold voltage Vth of the MONOS element. Impurities are implanted into the semiconductor substrate SUB through the opening of the resist pattern PR3 by ion implantation or the like so that an impurity region IR is formed in the surface of the semiconductor substrate SUB.

At this time, since the impurity region IR is formed between the gate electrodes GE in a self-aligned manner, it is unnecessary to consider a margin to compensate for misalignment or dimensional errors, unlike the resist pattern PR1 shown in FIG. 14. After that, the resist pattern PR3 is removed by ashing or the like.

As shown in FIG. 36, an ONO film which includes a silicon oxide film SO, a silicon nitride film SIN, and a silicon oxide film SO is formed over the surface of the semiconductor substrate SUB in a manner to cover the gate electrodes GE of the transistors other than the MONOS elements. A conductive film GEA, for example, of doped polysilicon is formed over the ONO film. The conductive film GEA may be a doped polysilicon film obtained by implanting impurities into non-doped polycrystalline silicon after film formation or a doped polysilicon film obtained by doping phosphorous or the like during film formation.

The ONO film is to become the gate insulating film of the MONOS element. The conductive film GEA is to become the gate electrode of the MONOS element.

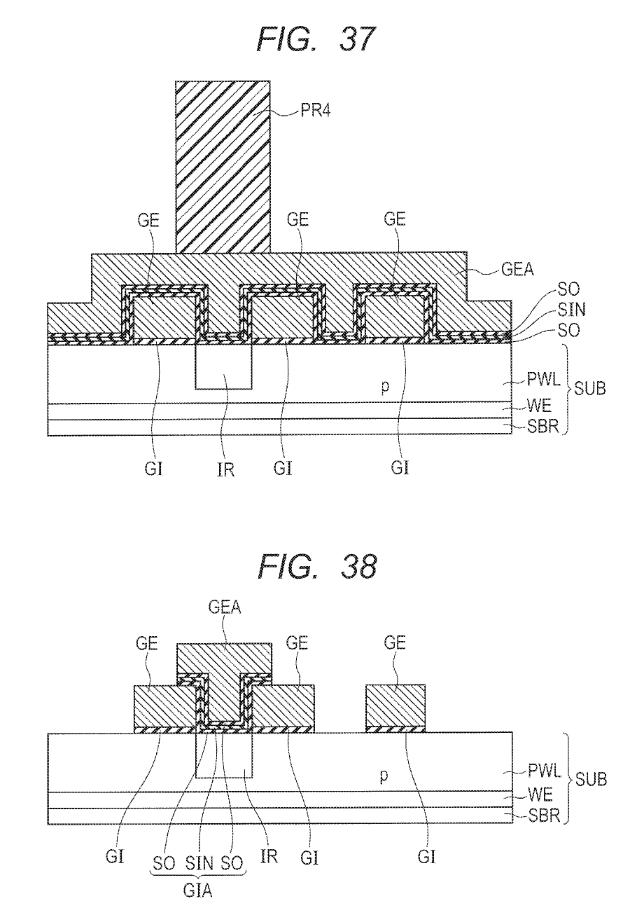

As shown in FIG. 37, a resist pattern PR4 is made over the conductive film GEA of the MONOS element by a usual photoengraving technique. In the formation of the resist pattern PR4, the MONOS element is formed between the gate electrodes GE. For this reason, unlike the resist pattern PR2 shown in FIG. 18, it is unnecessary to make a clearance in the horizontal direction (direction along the surface of the semiconductor substrate SUB) between the previously formed gate electrodes.

The resist pattern PR4 is located lust above the impurity region IR. Using the resist pattern PR4 as a mask, patterning is done on the conductive film GEA and ONO film by dry etching or the like. After that, the resist pattern. PR4 is removed by ashing or the like.

As shown in FIG. 38, a gate insulating film GIA as an ONO film for the MONOS element is formed by dry etching or the like as mentioned above, in a manner to contact the side surfaces and upper surfaces of both the two gate electrodes GE. Also, a gate electrode GEA for the MONOS element is formed just above the two gate electrodes GE through the gate insulating film GIA.

During etching to form the gate electrode GEA of the MONOS element, the gate electrodes GE of the transistors other than the MONOS element are not etched because they are covered with the ONO film. The conductive film GEA in the form of a sidewall spacer remains on the sidewalls of the gate electrodes GE of the transistors other than the MONOS element. The conductive film GEA in the form of a sidewall spacer is removed by isotropic dry etching or the like.

As shown in FIG. 39, impurities are introduced into the surface of the semiconductor substrate SUB by ion implantation or the like, using all the gate electrodes GEA and GE as a mask. Consequently, low concentration impurity regions SDL which constitute the LDD structures of the transistors other than the MONOS element are formed in the surface of the semiconductor substrate SUB.

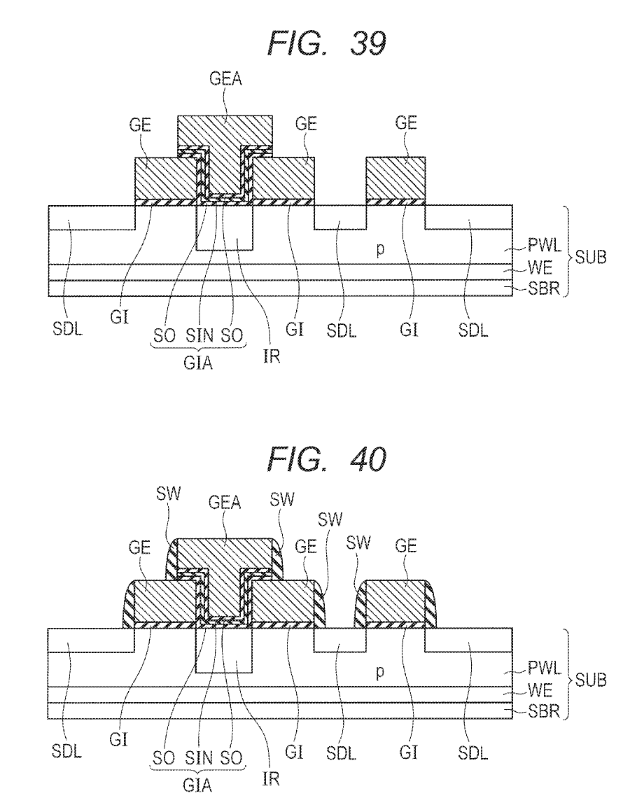

As shown in FIG. 40, sidewall insulating films SW are formed on the sidewalls of all the gate electrodes GEA and GE. The sidewall insulating films SW are, for example, silicon nitride films. After that, impurities are introduced into the surface of the semiconductor substrate SUB by ion implantation or the like, using all the gate electrodes GEA and GE and the sidewall insulating films SW as a mask. Consequently, high concentration impurity regions SDH are formed in the surface of the semiconductor substrate SUB. A high concentration impurity region SDH and a low concentration impurity region SDL make up a source/drain region SD which has an LDD structure.

By taking the above steps, MONOS elements MTR1 and MTR2 and other transistors AC1, AC2, and TR1 to TR4 are formed on the surface of the semiconductor substrate SUB. After that, the semiconductor device according to the third embodiment as shown in FIGS. 28 to 32 is completed by taking the same steps as those shown in FIGS. 22 to 27 in the second embodiment.

Next, the effects of the semiconductor device according to the third embodiment will be described.

As compared with the comparative example shown in FIG. 4, no flip flop circuit is provided in this embodiment. For this reason, latch-ups attributable to a CMOS transistor can be prevented.

Since the memory cell includes the capacitors CA1 and CA2, soft errors can be suppressed as in the first embodiment.

Furthermore, since no flip flop circuit is provided, the plane area occupied by the memory cell can be further decreased while occurrence of soft errors is prevented and occurrence of latch-ups is suppressed.

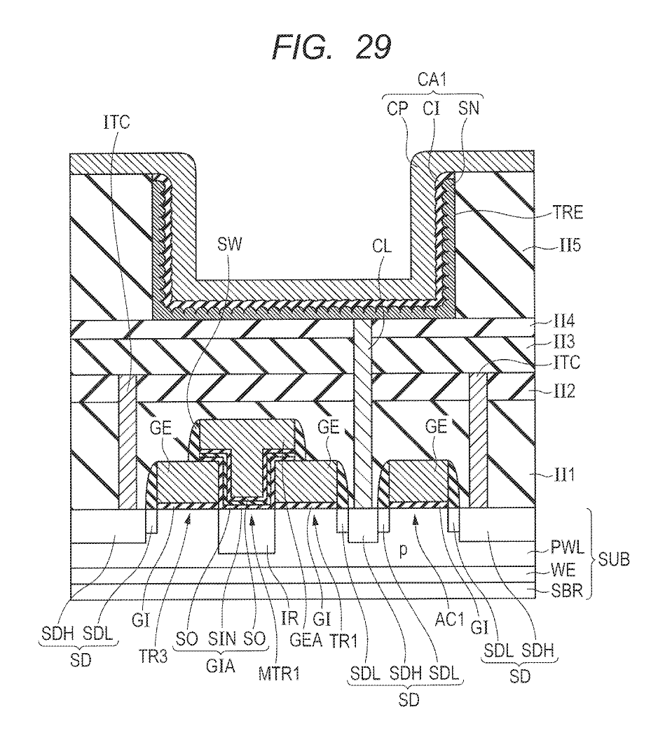

As shown in FIGS. 28 and 29, the capacitors CA1 and CA2 are also located just above the non-volatile memory parts. Therefore, the area where the storage node SN and cell plate CP of each of the capacitors CA1 and CA2 face each other can be increased. Consequently, the capacitance of the capacitors CA1 and CA2 can be increased and operation of the memory cell can be stabilized.

As shown in FIGS. 28 and 29, the gate electrode GEA of the MONOS element MTR1 lies over the gate electrodes GE of the transistors TR4 and TR3. Also, the gate electrode GEA of the MONOS element MTR2 lies over the gate electrodes GE of the transistors TR2 and TR4. For this reason, it is unnecessary to provide a clearance in the horizontal direction (direction along the surface of the semiconductor substrate) between the gate electrode GEA of the MONOS element MTR1 and the gate electrodes GE of the MOS transistors TR1 and TR3. Also, it is unnecessary to provide a clearance in the horizontal direction between the gate electrode GEA of the MONOS element MTR2 and the gate electrodes GE of the MOS transistors TR2 and TR4. Therefore, the plane area occupied by the memory cell can be further decreased.

As shown in FIG. 35, using the gate electrodes GE of the MOS transistors TR1 to TR4 as a mask, ion implantation is performed to control the threshold voltage Vth of the MONOS elements MTR1 and MTR2. Since ion implantation to control the threshold voltage Vth of the MONOS elements MTR1 and MTR2 is thus performed in a self-aligned manner, it is unnecessary to consider a margin to compensate for misalignment or dimensional errors, unlike the resist pattern PR1 shown in FIG. 14. Therefore, ion implantation to control the threshold voltage Vth of the MONOS elements MTR1 and MTR2 can be performed in a controllable manner.

### Other Embodiments

In the first to third embodiments, the non-volatile memory elements MTR1 and MTR2 are assumed to be transistors or elements which have a MONOS structure. However, instead the non-volatile memory may be a ReRAM, MRAM or PRAM.

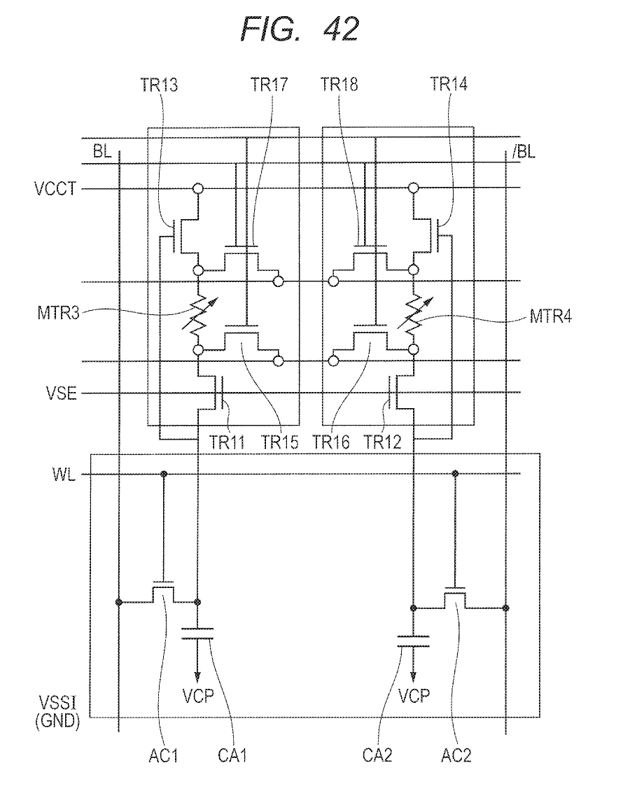

A ReRAM is a non-volatile memory element which takes advantage of change in the resistance of transition metal oxide film. An MRAM is a non-volatile memory element which takes advantage of the magnetoresistance of magnetic material. A PRAM is a non-volatile memory element which takes advantage of chalcogenide crystallinity. If a ReRAM, MRAM or PRAM is used, ac circuit such as the one shown in FIG. 42 is adopted.

As shown in FIG. 42, a ReRAM, MRAM or PRAM is used for each of the non-volatile memory elements MTR3 and MTR4. In this case, a MOS transistor TR11 is electrically coupled between the non-volatile memory element MTR1 and the first memory node N1. A MOS transistor TR13 is electrically coupled between the non-volatile memory element MTR1 and the wiring VCCT. The gate electrode of the MOS transistor TR13 is electrically coupled to the first memory node N1. MOS transistors TR15 and TR17 for applying an electric current are electrically coupled to both sides of the non-volatile memory element MTR1. The MOS transistors TR15 and TR17 enable initialization of the non-volatile memory element MTR3.

Also, a MOS transistor TR12 is electrically coupled between the non-volatile memory element MTR4 and the second memory node N2. A MOS transistor TR14 is electrically coupled between the non-volatile memory element MTR4 and the wiring VCCT. The gate electrode of the MOS transistor TR14 is electrically coupled to the second memory node N2. MOS transistors TR16 and TR18 for applying an electric current are electrically coupled to both sides of the non-volatile memory element MTR4. The MOS transistors TR16 and TR18 enable initialization of the non-volatile memory element MTR4.

The other details of the circuit configuration shown in FIG. 42 are almost the same as those of the circuit configuration shown in FIG. 5 and the same elements shown in FIG. 42 as in the circuit shown in FIG. 5 are designated by the same reference signs and their description is not repeated here.

The invention made by the present inventors has been so far explained concretely in reference to the preferred embodiments thereof. However, the invention is not limited to the above embodiments and it is obvious that these details may be modified in various ways without departing from the gist thereof.

What is claimed is:

1. A semiconductor device comprising:
a first bit line;
a first access transistor with a pair of source/drain, in which one of the paired source/drain is electrically coupled to a first memory node and the other of the paired source/drain is electrically coupled to the first bit line;
a first write switch element electrically coupled to the first memory node;
a first non-volatile memory element electrically coupled to the first memory node through the first write switch element; and
a first capacitor which includes a first storage node electrically coupled to the first memory node and a first cell plate to form a capacitance between the first storage node and the first cell plate.

2. The semiconductor device according to claim 1, wherein the first storage node is located just above at least a partial area of a first non-volatile memory part including the first non-volatile memory element and the first write switch element.

3. The semiconductor device according claim 1, further comprising a first reset switch element electrically coupled to the first non-volatile memory element.

4. The semiconductor device according to claim 3,
wherein the first non-volatile memory element has a gate insulating film with a charge capture part and a gate electrode,
wherein the first write switch element and the first reset switch element each have a gate electrode, and
wherein the gate insulating film of the first non-volatile memory element is in direct contact with the gate electrode of each of the first write switch element and the first reset switch element.

5. The semiconductor device according to claim 4, wherein the gate electrode of the first non-volatile memory element is located just above the gate electrode of each of the first write switch element and the first reset switch element with the gate insulating film of the first non-volatile memory element interposed therebetween.

6. The semiconductor device according to claim 1, further comprising:
a second bit line, together with the first bit line, constituting a bit line pair;
a second access transistor having a pair of source/drain, in which one of the paired source/drain is electrically coupled to a second memory node and the other of the paired source/drain is electrically coupled to the second bit line;
a second write switch element electrically coupled to the second memory node;
a second non-volatile memory element electrically coupled to the second memory node through the second write switch element; and
a second capacitor which includes a second storage node electrically coupled to the second memory node and a second cell plate to form a capacitance between the second storage node and the second cell plate.

7. The semiconductor device according to claim 6, wherein the second storage node is located just above at least a partial area of a second non-volatile memory part including the second non-volatile memory element and the second write switch element.

8. The semiconductor device according to claim 7, further comprising a second reset switch element electrically coupled to the second non-volatile memory element.

9. The semiconductor device according to claim 8,
wherein the second non-volatile memory element has a gate insulating film with a charge capture part and a gate electrode,
wherein the second write switch element and the second reset switch element each have a gate electrode, and
wherein the gate insulating film of the second non-volatile memory element is in direct contact with the gate electrode of each of the second write switch element and the second reset switch element.

10. The semiconductor device according to claim 9, wherein the gate electrode of the second non-volatile memory element is located just above the gate electrode of each of the second write switch element and the second reset switch element with the gate insulating film of the second non-volatile memory element interposed therebetween.

11. The semiconductor device according to claim 6, further comprising:
a flip flop circuit comprising: a first inverter including a first load transistor and a first driver transistor; and a second inverter including a second load transistor and a second driver transistor,
wherein the first inverter is electrically coupled to the first memory node and structured to be controlled by potential of the second memory node, and
wherein the second inverter is electrically coupled to the second memory node and structured to be controlled by potential of the first memory node.

12. The semiconductor device according to claim 11, wherein each of the first load transistor and the second load transistor is a thin film transistor.

13. A semiconductor device manufacturing method comprising the steps of:
forming an access transistor having a pair of source/drain with one of the paired source/drain electrically coupled to a memory node, a switch element electrically coupled to the memory node, and a non-volatile memory element electrically coupled to the memory node through the switch element;
forming a bit line electrically coupled to the other of the paired source/drain of the access transistor; and
forming a capacitor which includes a storage node electrically coupled to the memory node and a cell plate to form a capacitance between the storage node and the cell plate.

14. The semiconductor device manufacturing method according to claim 13,
wherein the switch element is formed in a manner to have a gate electrode, and
wherein ion implantation to control threshold voltage of the non-volatile memory element is performed using the gate electrode of the switch element as a mask.

15. The semiconductor device manufacturing method according to claim 14,
wherein the non-volatile memory element is formed in a manner to have an insulating film with a charge capture part and a gate electrode,
wherein the insulating film of the non-volatile memory element is formed in a manner to be in direct contact with both a side surface and an upper surface of the gate electrode of the switch element, and
wherein the gate electrode of the non-volatile memory element is formed in a manner to be located just above the gate electrode of the switch element with the insulating film of the non-volatile memory element interposed therebetween.
